(19) United States
(12) Patent Application Publication
(10) Pub. No.: US 2023/0275217 A1
(43) Pub. Date: Aug. 31, 2023

(54) Electroactive Materials for Metal-Ion Batteries

(71) Applicant: Nexeon Limited, Abingdon (GB)

(72) Inventors: Silo Meoto, Abingdon (GB); Joshua Whittam, Abingdon (GB); Mauro Chiacchia, Abingdon (GB)

(21) Appl. No.: 18/143,582

(22) Filed: May 4, 2023

Related U.S. Application Data
(63) Continuation of application No. PCT/GB2021/053357, filed on Dec. 17, 2021.

(30) Foreign Application Priority Data
Dec. 18, 2020 (GB) 2020207.3

(51) Int. Cl. H01M 4/36; H01M 4/587; H01M 4/38; H01M 4/134; H01M 4/133; H01M 4/62; C01B 32/05

(52) U.S. Cl. CPC H01M 4/366; H01M 4/587; H01M 4/386; H01M 4/134; H01M 4/133; H01M 4/625; C01B 32/05; H01M 2004/021

(57) ABSTRACT

This invention relates in general to electroactive materials and a process for the preparation thereof. The electroactive particles comprise a comprise a porous particle framework, wherein the total pore volume of pores having pore diameter in the range from 3.5 to 100 nm is in the range from 0.3 to 2.4 cm3 per gram of the porous particle framework. The pores of the porous particle are at least partially occupied by a multilayer coating that is disposed on the internal pore surfaces of the porous particle framework. The multilayer coating comprises at least a first electroactive material layer, a second electroactive material layer, and a first interlayer material disposed between the first and second electroactive material layers.

This invention relates in general to electroactive materials that are suitable for use in electrodes for rechargeable metal-ion batteries, and more specifically to particulate materials having high electrochemical capacities that are suitable for use as anode active materials in rechargeable metal-ion batteries.

Rechargeable metal-ion batteries are widely used in portable electronic devices such as mobile telephones and laptops and are finding increasing application in electric or hybrid vehicles. Rechargeable metal-ion batteries generally comprise an anode in the form of a metal current collector provided with a layer of an electroactive material, defined herein as a material which is capable of inserting and releasing metal ions during the charging and discharging of a battery. The terms “cathode” and “anode” are used herein in the sense that the battery is placed across a load, such that the anode is the negative electrode. When a metal-ion battery is charged, metal ions are transported from the metal-ion-containing cathode layer via the electrolyte to the anode and are inserted into the anode material. The term “battery” is used herein to refer both to a device containing a single anode and a single cathode and to devices containing a plurality of anodes and/or a plurality of cathodes.

There is interest in improving the gravimetric and/or volumetric capacities of rechargeable metal-ion batteries. To date, commercial lithium-ion batteries have largely been limited to the use of graphite as an anode active material. When a graphite anode is charged, lithium intercalates between the graphite layers to form a material with the empirical formula LiₓC₆ (wherein x is greater than 0 and less than or equal to 1). Consequently, graphite has a maximum theoretical capacity of 372 mAh/g in a lithium-ion battery, with a practical capacity that is somewhat lower (ca. 340 to 360 mAh/g). Other materials, such as silicon, tin and germanium, are capable of intercalating lithium with a significantly higher capacity than graphite but have yet to find widespread commercial use due to difficulties in maintaining sufficient capacity over numerous charge/discharge cycles.

Silicon in particular has been identified as a promising alternative to graphite for the manufacture of rechargeable metal-ion batteries having high gravimetric and volumetric capacities because of its very high capacity for lithium (see, for example, Insertion Electrode Materials for Rechargeable Lithium Batteries, Winter, M. et al. in Adv. Mater. 1998, 10, No. 10). At room temperature, silicon has a theoretical maximum specific capacity in a lithium-ion battery of about 3,600 mAh/g (based on Li₁₅Si₄). However, the intercalation of lithium into bulk silicon leads to a large increase in the volume of the silicon material of up to 400% of its original volume when silicon is lithiated to its maximum capacity. Repeated charge-discharge cycles cause significant mechanical stress in the silicon material, resulting in fracturing and delamination of the silicon anode material. Volume contraction of silicon particles upon delithiation can result in a loss of electrical contact between the anode material and the current collector. A further difficulty is that the solid electrolyte interphase (SEI) layer that forms on the silicon surface does not have sufficient mechanical tolerance to accommodate the expansion and contraction of the silicon. As a result, newly exposed silicon surfaces lead to further electrolyte decomposition and increased thickness of the SEI layer and irreversible consumption of lithium. These failure mechanisms collectively result in an unacceptable loss of electrochemical capacity over successive charging and discharging cycles.

A number of approaches have been proposed to overcome the problems associated with the volume change observed when charging silicon-containing anodes. It has been reported that fine silicon structures below around 150 nm in cross-section, such as silicon films and silicon nanoparticles are more tolerant of volume changes on charging and discharging when compared to silicon particles in the micron size range. However, neither of these is suitable for commercial scale applications in their unmodified form; nanoscale particles are difficult to prepare and handle and silicon films do not provide sufficient bulk capacity.

WO 2007/083155 discloses that improved capacity retention may be obtained with silicon particles having high aspect ratio, i.e. the ratio of the largest dimension to the smallest dimension of the particle. The small cross-section of such particles reduces the structural stress on the material due to volumetric changes on charging and discharging. However, such particles may be difficult and costly to manufacture and can be fragile. In addition, high surface area may result in excessive SEI formation, resulting in excessive loss of capacity on the first charge-discharge cycle.

It is also known in general terms that electroactive materials such as silicon may be deposited within the pores of a porous carrier material, such as an activated carbon material. These composite materials provide some of the beneficial charge-discharge properties of nanoscale silicon particles while avoiding the handling difficulties of nanoparticles. Guo et al. (Journal of Materials Chemistry A, 2013, pp. 14075-14079) discloses a silicon-carbon composite material in which a porous carbon substrate provides an electrically conductive framework with silicon nanoparticles deposited within the pore structure of the substrate with uniform distribution. It is shown that the composite material has improved capacity retention over multiple charging cycles, however the initial capacity of the composite material in mAh/g is significantly lower than for silicon nanoparticles. The present inventors have previously reported the development of a class of electroactive materials having a composite structure in which nanoscale electroactive materials, such as silicon, are deposited into the pore network of a highly porous conductive particulate material, e.g. a porous carbon material.

For example, WO 2020/095067 and WO 2020/128495 report that the improved electrochemical performance of these materials can be attributed to the way in which the electroactive materials are located in the porous material in the form of small domains with dimensions of the order of a few nanometres or less. These fine electroactive structures are thought to have a lower resistance to elastic deformation and higher fracture resistance than larger electroactive structures, and are therefore able to lithiate and delithiate without excessive structural stress. As a result, the electroactive materials exhibit good reversible capacity retention over multiple charge-discharge cycles. Secondly, by controlling the loading of silicon within the porous carbon framework such that only part of the pore volume is occupied by silicon in the uncharged state, the unoccupied pore volume of the porous particle framework is able to accommodate a substantial amount of silicon expansion internally. Furthermore, by locating nanoscale silicon domains within small mesopores and/or micropores as described above, only a small area of silicon surface is accessible to electrolyte and so SEI formation is limited. Additional exposure of silicon in subsequent charge-discharge cycles is substantially prevented such that SEI formation is not a significant failure mechanism leading to capacity loss. This stands in clear contrast to the excessive SEI formation that characterizes the material disclosed by Guo, for example (see above).

The materials described in WO 2020/095067 and WO 2020/128495 has been synthesized by chemical vapour infiltration (CVI) in different reactor systems (static, rotary and FBR). The porous particles are contacted with a flow of a silicon-containing precursor (CVI), typically silane gas, at atmospheric pressure and at temperatures between 400 to 700° C. until the required amount of silicon is deposited into micropores and small mesopores. The materials described in WO 2020/095067 and WO 2020/128495 require careful control of the pore size distribution of the porous particles as well as the amount of silicon deposited in order to obtain fine electroactive structures that are able to lithiate and delithiate with good reversible capacity retention over multiple charge-discharge cycles. In particular, the materials described in WO 2020/095067 and WO 2020/128495 comprise porous particle frameworks in which a relatively high proportion of the pore volume is in the form of micropores (pore diameter <2 nm) or fine mesopores (e.g. pore diameter <20 nm or <10 nm). In particular, WO 2020/095067 and WO 2020/128495 disclose that optimum results may be obtained when the volume fraction of micropores is at least 50 vol % of the total pore volume of micropores and mesopores.

If porous particles having a more open pore structure (i.e. a volumetric pore size distribution more toward larger mesopores and macropores) are used to prepare this type of composite particle, it is found that inferior electrochemical performance is obtained. It is believed that the larger pores result in the deposition of coarser silicon domains and a higher exposed surface area of the deposited silicon. This results in poor initial capacity due to oxygenation of the exposed silicon surface, a high first cycle loss due to initial SEI formation, and poor reversible capacity retention due to excessive structural stress and uncontrolled SEI formation on subsequent charge-discharge cycles.

It would therefore be desirable to extend the technology described in WO 2020/095067 and WO 2020/128495 to a broader range of porous particle frameworks without the disadvantages described above. It has now been found that this problem can be addressed when the electroactive material is present in the pores of a porous particles form of a multilayer structure in which a plurality layers of electroactive material are alternated with spacer layers of a different chemical species. An intercalated multilayer structure may be formed using a CVI process wherein different chemical species are deposited layer-by-layer until the required multilayer structure is formed. Within this generic structure are provided a range of options in terms of the number of layers, the chemical composition of each layer, and the thickness of each layer.

In a first aspect, the invention provides a particulate material consisting of a plurality of composite particles, wherein the composite particles comprise:
(a) a porous particle framework, wherein the total pore volume of pores having pore diameter in the range from 3.5 to 100 nm is P¹ cm³ per gram of the porous particle framework, as determined by nitrogen gas adsorption, where P¹ represents a number in the range from 0.3 to 2.4;
(b) a multilayer coating disposed on the internal pore surfaces of the porous particle framework, wherein the multilayer coating comprises at least:
   (i) a first electroactive material layer;
   (ii) a second electroactive material layer; and
   (iii) a first interlayer material disposed between the first and second electroactive material layers.

A number of different factors contribute to the improved performance of these materials when compared to materials prepared using similar porous particle frameworks, but wherein the electroactive material is deposited as a single homogenous mass. The multilayer structure is able to act as a filler to reduce the residual surface area and therefore minimise SEI formation and oxygenation of the electroactive material surface. In addition, the layered structure of the electroactive material mitigates volumetric expansion in the layer thickness direction via mechanical buffering by the interlayer material, with stress released in the longitudinal direction. The multi-layer structure also reduces SEI formation since the innermost layers of electroactive material are not exposed to electrolyte and therefore SEI formation on these layers is effectively impeded. The interlayer materials of the multilayer structure may also act as a conductive component, for example a conductive carbon layer may be used as the interlayer material. This is believed to improve the rate performance of the composite particles.

As used herein, the terms “multilayer coating”, “first electroactive material layer”, “second electroactive material layer”, and “first interlayer material” define a particle structure that is consistent with the sequential deposition of a first electroactive material, a first interlayer material and a second electroactive material into the pore structure of the porous particle framework. Thus, the electroactive material does not form an extended network throughout the pore space but is interrupted by the interlayer material(s). Thus, within at least part of the pore volume there is an assembly of material that follows the sequence:

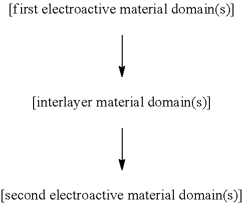

This sequence may be extended, both before and after, by additional electroactive material domains and/or by additional interlayer material domains as appropriate. The interlayer material domains located between adjacent electroactive material domains may act as barriers that separate the electroactive material domains, limiting the length scale of continuous electroactive material domains within the composite particles.

The electroactive material layers and interlayer material may form discrete domains, with a sharp boundary between the two, or there may be a composition gradient between the electroactive material layers and the interlayer material. Interlayer material may be chemically bonded (e.g. covalently, ionically or metallically bonded) to the first and/or second electroactive material layers. For example, the interlayer material may comprise a passivation layer at the surface of the first electroactive material layer, or an alloy of the electroactive material at the surface of the electroactive material, or a doped electroactive material at the surface of the electroactive material. Alternatively, interlayer materials may not be chemically bonded to electroactive material layers.

As a result of the method of manufacturing, the layered structure may not be uniform throughout the particle, for instance the thickness of the various layers may vary and the layers need not be coterminous. However, the composite particles will exhibit the ordering of layers/domains of the electroactive materials and interlayer materials as set out above that results from the inventive process described herein.

The porous particle framework is preferably a conductive porous particle framework. A conductive porous particle framework improves the rate performance of the composite particles by facilitating charge transfer during lithiation and delithiation of the electroactive material.

A preferred conductive porous particle framework is a conductive porous carbon particle framework. The conductive porous carbon particle framework preferably comprises at least 80 wt % carbon, more preferably at least 85 wt % carbon, more preferably at least 90 wt % carbon, more preferably at least 95 wt % carbon, and optionally at least 98 wt % or at least 99 wt % carbon. The carbon may be crystalline carbon or amorphous carbon, or a mixture of amorphous and crystalline carbon. The conductive porous carbon particle framework may be either a hard carbon particle framework or a soft carbon particle framework.

As used herein, the term “hard carbon” refers to a disordered carbon matrix in which carbon atoms are found predominantly in the sp² hybridised state (trigonal bonds) in nanoscale polyaromatic domains. The polyaromatic domains are cross-linked with a chemical bond, e.g. a C—O—C bond. Due to the chemical cross-linking between the polyaromatic domains, hard carbons cannot be converted to graphite at high temperatures. Hard carbons have graphite-like character as evidenced by the large G-band (˜1600 cm⁻¹) in the Raman spectrum. However, the carbon is not fully graphitic as evidenced by the significant D-band (˜1350 cm⁻¹) in the Raman spectrum.

As used herein, the term “soft carbon” also refers to a disordered carbon matrix in which carbon atoms are found predominantly in the sp² hybridised state (trigonal bonds) in polyaromatic domains having dimensions in the range from 5 to 200 nm. In contrast to hard carbons, the polyaromatic domains in soft carbons are associated by intermolecular forces but are not cross-linked with a chemical bond. This means that they will graphitise at high temperature. The conductive porous carbon particle framework preferably comprises at least 50% sp² hybridised carbon as measured by XPS. For example, the conductive porous carbon particle framework may suitably comprise from 50% to 98% sp² hybridised carbon, from 55% to 95% sp² hybridised carbon, from 60% to 90% sp² hybridised carbon, or from 70% to 85% sp² hybridised carbon.

A variety of different materials may be used to prepare suitable conductive porous carbon particle frameworks. Examples of organic materials that may be used include plant biomass and fossil carbon sources such as coal. Examples of resins and polymeric materials which form porous carbon particles on pyrolysis include phenolic resins, novolac resins, pitch, melamines, polyacrylates, polystyrenes, polyvinylalcohol (PVA), polyvinylpyrrolidone (PVP), and various copolymers comprising monomer units of acrylates, styrenes, α-olefins, vinyl pyrrolidone and other ethylenically unsaturated monomers. A variety of different carbon materials are available in the art depending on the starting material and the conditions of the pyrolysis process. Porous carbon particles of various different specifications are available from commercial suppliers.

Mesopores and macropores may be obtained by known templating processes, using extractable pore formers such as MgO and other colloidal or polymer templates which can be removed by thermal or chemical means post pyrolysis or activation.

Alternatives to carbon-based particle frameworks include porous particle frameworks comprising titanium nitride (TiN), titanium carbide (TiC), and boron nitride (BN). Preferred are titanium nitride (TiN) and boron nitride (BN). Alternatively, a conductive porous particle framework may comprise a non-conductive porous particle framework wherein the internal pore surfaces of the porous particle framework are provided with a conductive coating, such as a conductive pyrolytic carbon coating.

The porous particle framework comprises a three-dimensionally interconnected open pore network comprising macropores and/or mesopores and optionally a minor volume of micropores. In accordance with conventional IUPAC terminology, the term “micropore” is used herein to refer to pores of less than 2 nm in diameter, the term “mesopore” is used herein to refer to pores of 2 to 50 nm in diameter, and the term “macropore” is used to refer to pores of greater than 50 nm diameter.

References herein to the volume of micropores, mesopores and macropores in the porous particle framework, and also any references to the distribution of pore volume within the porous particle framework, shall be understood to relate to the internal pore volume of the porous particle framework taken in isolation (i.e. prior to the deposition the multilayer coating). References herein to the BET surface area of the porous particle framework shall also be understood to relate to the BET surface area porous particle framework taken in isolation.

The porous particle framework is characterised by the total volume of pores having pore diameter in the range from 3.5 to 100 nm, as determined by nitrogen gas adsorption. The total volume of pores in this range is defined as P¹ cm³ per gram of the conductive porous particle framework as determined by nitrogen gas adsorption, wherein P¹ represents a dimensionless number in the range from 0.3 to 2.4 (e.g. if the total volume of pores in the range 3.5 to 100 nm is 1.2 cm³/g, then P¹=1.2). Preferably, P¹ is from 0.6 to 2.4.

Typically, the porous particle framework includes both macropores and mesopores.

However, it is not excluded that porous particle frameworks may be used that have a pore size distribution including macropores and no mesopores, or mesopores and no macropores. Pore volume measured above 100 nm is assumed for the purposes of the invention to be inter-particle porosity and is disregarded.

References herein to the volume of pores having diameters in the range from 0 to 100 nm (including sub-ranges thereof) shall be understood as meaning pore volumes as measured by nitrogen gas adsorption at 77 K by the Barrett-Joyner-Halenda (BJH) method in accordance with ISO 15901-2, and using a relative pressure range p/p₀ of 1 to 10⁻⁴ (referred to herein as “the BJH method”). Nitrogen gas adsorption is a technique that characterizes the porosity and pore diameter distributions of a material by allowing a gas to condense in the pores of a solid. As pressure increases, the gas condenses first in the pores of smallest diameter and the pressure is increased until a saturation point is reached at which all of the pores are filled with liquid. The nitrogen gas pressure is then reduced incrementally, to allow the liquid to evaporate from the system. Analysis of the adsorption and desorption isotherms, and the hysteresis between them, allows the pore volume and pore size distribution to be determined. Suitable instruments for the measurement of pore volume and pore size distributions using the BJH method include the TriStar II and TriStar II Plus porosity analyzers, which are available from Micromeritics Instrument Corporation, USA, and the Autosorb IQ porosity analyzers, which are available from Quantachrome Instruments.

P¹ preferably has a value of at least 0.4, or at least 0.5, or at least 0.6, or at least 0.7, or at 10 least 0.8, or at least 0.85, or at least 0.9, or at least 0.95, or at least 1, or at least 1.05, or at least 1.1, or at least 1.15, or at least 1.2. The use of high porosity porous particle frameworks may be advantageous since it allows a larger amount of silicon to be accommodated within the pore structure.

The internal pore volume of the porous particle framework is suitably capped at a value at which increasing fragility of the framework outweighs the advantage of increased pore volume accommodating a larger amount of silicon. Preferably P¹ is no more than 2.3, or no more than 2.2, or no more than 2.1, or no more than 2, or no more than 1.95, or no more than 1.9, or no more than 1.85, or no more than 1.8.

P¹ is preferably in the range from 0.6 to 2.4, or from 0.7 to 2.4, or from 0.8 to 2.3, or from 0.9 to 2.2, or from 0.95 to 2.1, or from 1 to 2, or from 1.05 to 1.95, or from 1.1 to 1.9, or from 1.15 to 1.85, or from 1.2 to 1.8.

The PD₅₀ pore diameter of the porous particle framework is preferably at least 10 nm, or at least 20 nm, or at least 25 nm, or at least 30 nm, or at least 35 nm, or at least 40 nm, or at least 45 nm, or at least 50 nm. The term “PD₅₀ pore diameter” as used herein refers to the volume-based median pore diameter, based on the total volume of pores having pore diameter from 3.5 to 100 nm in the porous particle framework. Therefore, in accordance with the invention, at least 50% of the total volume of pores having pore diameter from 3.5 to 100 nm is preferably in the form of pores having a diameter of at least 10 nm.

It will be appreciated that gas adsorption is effective only to determine the pore volume of pores that are accessible to nitrogen from the exterior of a porous material. Porosity values specified herein shall be understood as referring to the volume of open pores, i.e. pores that are accessible to a fluid from the exterior of the porous particles. Fully enclosed pores which cannot be identified by nitrogen adsorption shall not be taken into account herein when determining porosity values.

The pore size distribution in the porous particle framework is preferably such that at least 50 vol % of the total volume of pores having pore diameter in the range from 3.5 to 100 nm is in pores having a pore diameter in the range from 5 to 60 nm. Therefore the volume fraction of pores having a pore diameter in the range from 5 to 60 nm is preferably at least 50 vol %, or at least 55 vol %, or at least 60 vol %, or at least 65 vol %, or at least 70 vol %, or at least 75 vol %, or at least 80 vol %, or at least 85 vol %, or at least 90 vol %, based on the total pore volume of pores having pore diameter in the range from 3.5 to 100 nm in the porous particle framework.

More preferably, at least 50 vol % of the total volume of pores having pore diameter in the range from 3.5 to 100 nm is in the form of pores having a pore diameter in the range from 10 to 50 nm. Therefore, the volume fraction of pores having a pore diameter in the range from 10 to 50 nm is preferably at least 50 vol %, or at least 55 vol %, or at least 60 vol %, or at least 65 vol %, or at least 70 vol %, or at least 75 vol %, or at least 80 vol %, or at least 85 vol %, or at least 90 vol %, based on the total pore volume of pores having pore diameter in the range from 3.5 to 100 nm in the porous particle framework.

The BJH method for the analysis of pore volumes and pore size distributions is effective for pores having diameters of 3.5 nm and above but is inappropriate for pore sizes below 3.5 nm. References herein to the volume of pores having diameters below 3.5 nm (including sub-ranges thereof) shall be understood as meaning pore volumes as measured by nitrogen gas adsorption at 77 K down to a relative pressure p/p₀ of 10⁻⁶ using quenched solid density functional theory (QSDFT) in accordance with standard methodology as set out in ISO 15901-2 and ISO 15901-3 (referred to herein as “the QSDFT method”). Suitable instruments for QSDFT measurements include the Autosorb IQ porosity analyzers available from Quantachrome Instruments.

The total volume of pores having diameter less than 3.5 nm in the porous particle framework is defined herein as P² cm³ per gram of the porous particle framework, wherein P² preferably represents a dimensionless number having a value of less than 0.5, or less than 0.45, or less than 0.4, or less than 0.35, or less than 0.3, or less than 0.25, or less than 0.2, or less than 0.15, or less than 0.1, as determined by nitrogen gas adsorption (e.g. if the total volume of pores having diameter less than 3.5 nm is 0.1 cm³/g, then P²=0.1).

Optionally, the value of P² may be defined relative to the value of P¹. Preferably, P² represents a number that is no more than [1×P1], or no more than [0.8×P1], or no more than [0.6×P1], or no more than [0.5×P1], or no more than [0.4×P1], or no more than [0.3×P1], or no more than [0.2×P1], or no more than [0.1×P1].

The porous particle framework preferably has a BET surface area of at least 150 m²/g, more preferably at least 250 m²/g, optionally at least 500 m²/g, or at least 750 m²/g, or at least 1,000 m²/g, or at least 1,250 m²/g. The term “BET surface area” as used herein should be taken to refer to the surface area per unit mass calculated from a measurement of the physical adsorption of gas molecules on a solid surface, using the Brunauer—Emmett—Teller theory, in accordance with ISO 9277. Preferably, the BET surface area of the porous particle framework is no more than 2,500 m²/g, preferably no more than 2,000 m²/g, or no more than 1,750 m²/g, or no more than 1,500 m²/g. For example, the porous particle framework may have a BET surface area in the range from 250 m²/g to 2,500 m²/g, or from 500 m²/g to 2,500 m²/g, or from 750 m²/g to 2,000 m²/g, or from 750 m²/g to 1,750 m²/g, or from 750 m²/g to 1,500 m²/g, or from 1,000 to 2,000 m²/g, or from 1,000 m²/g to 1,750 m²/g, or from 1,000 m²/g to 1,500 m²/g, or from 1,250 m²/g to 2,000 m²/g, or from 1,250 m²/g to 1,750 m²/g, or from 250 m²/g to 2,000 m²/g, or from 250 m²/g to 1,750 m²/g, or from 500 m²/g to 1,500 m²/g.

The electroactive materials in the first and second electroactive material layers may be the same or different, and may optionally be independently selected from elemental silicon, elemental tin, elemental germanium, elemental aluminium, and mixtures and alloys thereof.

Preferably, the electroactive materials in the first and second electroactive material layers are elemental silicon, elemental tin, elemental germanium, and mixtures and alloys thereof, optionally wherein said mixture and alloys may comprise aluminium.

A preferred electroactive material is silicon. Preferably, at least one of the first and second electroactive material layers comprises or consists of elemental silicon. More preferably, both the first and the second electroactive material layers comprise or consists of elemental silicon.

As used herein, the term “interlayer material” refers to a layer of material disposed between two adjacent electroactive material layers and having a distinct chemical composition from the electroactive material layers. Accordingly, the multilayer coating has a periodic structure with alternating layers of electroactive material and interlayer materials. The electroactive material layers and interlayer materials may be discrete layers, with a sharp boundary between the two, or there may be a composition gradient between the electroactive material layers and the interlayer material.

The first interlayer material preferably comprises one or more of carbon, nitrogen and/or oxygen.

The first interlayer material may comprise or consist of a passivation layer formed on the surface of the first electroactive material layer.

One type of passivation layer is a native oxide layer that is formed, for example, by exposing the surface of the first electroactive material layer to air or another oxygen containing gas prior to deposition of the second electroactive material layer. In the case that the first electroactive material layer is silicon, the first interlayer material may comprise a silicon oxide of the formula SiOₓ, wherein 0<x≤2. The silicon oxide is preferably amorphous silicon oxide.

Another type of passivation layer is a nitride layer that is formed, for example, by exposing the surface of the first electroactive material layer to ammonia or another nitrogen containing molecule prior to deposition of the second electroactive material layer. In the case that the first electroactive material layer is silicon, the first interlayer material may comprise a silicon nitride of the formula SiNₓ, wherein 0<x≤ 4/3. The silicon nitride is preferably amorphous silicon nitride. Nitride interlayer materials are preferred to oxide passivation layers. As sub-stoichiometric nitrides (such as SiNₓ, wherein 0<x≤ 4/3) are conductive, nitride interlayers function as a conductive network that allows for faster charging and discharge of the electroactive material.

Another type of passivation layer is an oxynitride layer that is formed, for example, by exposing the surface of the first electroactive material layer to ammonia (or another nitrogen containing molecule) and oxygen gas prior to deposition of the second electroactive material layer. In the case that the first electroactive material layer is silicon, the first interlayer material may comprise a silicon oxynitride of the formula SiOₓN_{y}, wherein 0<x<2, 0<y< 4/3, and 0<(2x+3y)≤4). The silicon oxynitride is preferably amorphous silicon oxynitride.

Another type of passivation layer is a carbide layer. In the case that the first electroactive material layer is silicon, the first interlayer may comprise a silicon carbide of the formula SiCₓ, wherein 0<x≤1. The silicon carbide is preferably amorphous silicon carbide. A silicon carbide layer may be formed by contacting the surface of the first electroactive material with carbon containing precursors, e.g. methane or ethylene at elevated temperatures.

As a further alternative, a passivation layer may comprise a carbon-containing organic moiety covalently bonded to the surface of the first electroactive material layer. A covalently bonded organic interlayer may be formed by insertion of an organic compounds into an M—H group at the surface of the electroactive material (where M represents an atom of the electroactive material) to form a covalently passivated surface which is resistant to oxidation by air. When silicon is the electroactive material, the passivation reaction between the silicon surface and the passivating agent may be understood as a form of hydrosilylation, as shown schematically below.

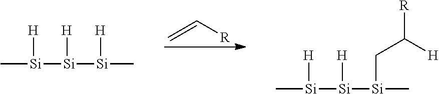

Suitable organic compounds that may be used to form the first interlayer material via passivation of the surface of the first electroactive material layer include compounds comprising an alkene, alkyne or carbonyl functional group, more preferably a terminal alkene, terminal alkyne or aldehyde group. For example, the first interlayer material may be formed by passivation of the surface of the first electroactive material layer with one or more compounds of the formulae:

R¹—CH═CH—R¹; (i)

R¹—C≡C—R¹; (ii)

O═CH—R¹; and (iii)

Wherein each R¹ independently represents H or an unsubstituted or substituted aliphatic or aromatic hydrocarbyl group having from 1 to 20 carbon atoms, preferably from 2 to 10 carbon atoms, or wherein two R groups in formula (i) form an unsubstituted or substituted hydrocarbyl ring structure comprising from 3 to 8 carbon atoms in the ring.

Particularly preferred passivating agents include one or more compounds of the formulae:

CH₂═CH—R¹; and (i)

HC≡C—R¹; (ii)

wherein R¹ is as defined above. Preferably, R¹ is unsubstituted.

Particular examples of suitable organic compounds that may be used to form the first interlayer material via passivation of the surface of the first electroactive material layer include ethylene, propylene, 1-butene, butadiene, 1-pentene, 1,4-pentadiene, 1-hexene, 1-octene, styrene, divinylbenzene, acetylene, phenylacetylene, norbornene, norbornadiene bicyclo[2.2.2]oct-2-ene, camphene, 3-carene, sabinene, thujene, pinene, limonene, acetylene, phenylacetylene, anthraquinone, anthrone, and camphor. Mixtures of different passivating agents may also be used.

Further examples of organic compounds that may be used to form the first interlayer material via passivation of the surface of the first electroactive material layer include compounds including an active hydrogen atom bonded to oxygen, nitrogen, sulphur or phosphorus. For example, the passivating agent may be an alcohol, amine, thiol or phosphine. Reaction of the group —XH with hydride groups at the surface of the electroactive material is understood to result in elimination of H₂ and the formation of a direct bond between X and the electroactive material surface.

Suitable passivating agents in this category include compounds of the formula

HX—R², (iv)

HX—C(O)—R¹, (v)

wherein X represents O, S, NR or PR, and wherein each R¹ is independently as defined above and R² represents an unsubstituted or substituted aliphatic or aromatic hydrocarbyl group having from 1 to 20 carbon atoms, or R¹ and R² together form an unsubstituted or substituted hydrocarbyl ring structure comprising from 3 to 8 carbon atoms in the ring.

Preferably X represents O or NH.

Preferably, R² represents an optionally substituted aliphatic or aromatic group having from 2 to 10 carbon atoms. Amine groups may also be incorporated into a 4-10 membered aliphatic or aromatic ring structure, as in pyrrolidine, pyrrole, imidazole, piperazine, indole, or purine.

The first interlayer material may comprise a conductive pyrolytic carbon material. A conductive pyrolytic carbon layer may be formed by CVI using a suitable carbon-containing precursor, as discussed in further detail below. Optionally, the first interlayer material may comprise a conductive pyrolytic carbon material layer over a passivation layer as defined above.

The first interlayer material may comprise a conductive metallic element or metal alloy. A conductive metal or metal alloy layer may be formed by CVI using a suitable metal-containing precursor, as discussed in further detail below. An example of a suitable conductive metal interlayer material is silver metal. Optionally, the first interlayer material may comprise a conductive metal or metal alloy layer over a passivation layer as defined above.

The first interlayer material may comprise a lithium-ion permeable solid electrolyte. Examples of suitable lithium permeable solid electrolytes include: garnet-type solid electrolytes (including “LLZO” electrolytes such as Li₇La₃Zr₂O₁₂ and Li_{6.5}La₃Ti_{0.5}Zr_{1.5}O₁₂); perovskite-type solid electrolytes (including “LLTO” electrolytes such as Li_{0.33}La_{0.57}TiO₃); LISICON-type solid electrolytes, NaSICON-type solid electrolytes (such as Li_{1.3}Al_{0.3}Ti_{1.7}(PO₄)₃); lithium phosphorous oxy-nitride (LiPON) solid electrolytes; Li₃N-type solid electrolytes; lithium phosphate (Li₃PO₄) solid electrolytes, lithium titanate (Li₄Ti₅O₁₂) solid electrolytes; lithium tantalate (LiTaO₃) solid electrolytes; sulfide-type solid electrolytes; argyrodite-type solid electrolytes; and anti-perovskite-type solid electrolytes. Variants (e.g. including dopants) and combinations of these electrolyte types are also included. Optionally, the first interlayer material may comprise a lithium permeable solid electrolytes layer over a passivation layer as defined above.

The multilayer coating may comprise additional electroactive material layers and interlayers to those mentioned above. For example, the multilayer coating may comprise n electroactive material layers and (n−1) interlayer materials disposed between each of the electroactive material layers, wherein n is an integer from 3 to 20, or from 3 to 15, or from 4 to 12, or from 4 to 10, or from 5 to 10, or from 5 to 8. Preferably, each of the n electroactive materials is independently as described above for the first and second electroactive materials. Preferably, each of the n electroactive materials is the same electroactive material, more preferably each of the n electroactive materials is elemental silicon. Preferably, each of the (n−1) interlayer materials is independently as described above for the first interlayer material. Optionally, each of the (n−1) interlayer materials is the same interlayer material. The thickness of the interlayer material is preferably less than 5 nm, more preferably, less than 2 nm, and most preferably less than 1 nm. It will be understood that thicker interlayers reduce the amount of electroactive material that can be accommodated within the pore volume of the porous particle framework. Accordingly, the average interlayer thickness is preferably less than 20%, or less than 10%, or less than 5% of the average thickness of the electroactive material layers.

The multilayer coating disposed on the internal pore surfaces of the porous particle framework may optionally further comprise:
(iv) a coating layer disposed on the surface of the outermost electroactive material layer (i.e. the last electroactive material layer to be formed and the most distal electroactive material layer from the pore wall of the porous particle framework).

Optionally, the coating layer (iv) may be formed from any of the materials used to form the interlayer materials as described above. The coating layer (iv) may be the same as, or different from, any of the interlayer materials.

The particulate material of the invention may have a range of electroactive material content. For example, the amount of silicon in the composite particles may be selected such that at least 25% and as much as 80% or more of the internal pore volume of the porous particle framework is occupied by the electroactive material(s) and interlayer material(s). For example, the electroactive material may occupy from 25% to 75%, or from 25% to 70%, or from 30% to 65%, or from 35 to 60%, or from 40 to 60%, or from 25% to 45%, or from 30% to 40% of the internal pore volume of the porous particle framework. Within these preferred ranges, the pore volume of the porous particle framework is effective to accommodate expansion of the electroactive material during charging and discharging, but avoids excess pore volume which does not contribute to the volumetric capacity of the particulate particles. However, the amount of electroactive material is also not so high as to impede effective lithiation due to inadequate lithium ion diffusion rates or due to inadequate expansion volume resulting in mechanical resistance to lithiation.

Preferably at least 85 wt %, more preferably at least 90 wt %, more preferably at least 95 wt %, even more preferably at least 98 wt % of the electroactive material mass in the composite particles is located within the internal pore volume of the porous particle framework such that there is no or very little electroactive material located on the external surfaces of the composite particles. The reaction kinetics of the CVI process ensure that preferential deposition of silicon occurs on internal surfaces of the porous particle framework.

In the case that the electroactive material is silicon, the amount of silicon in the composite particles can be correlated to the available pore volume by the requirement that the mass ratio of silicon to the porous particle framework is in the range from [0.5×P¹ to 1.9×P¹]:1. This relationship takes into account the density of silicon and the pore volume of the porous particle framework to define a weight ratio of silicon at which the pore volume is around 20% to 80% occupied by the silicon.

In the case that the electroactive material is silicon, the composite particles preferably comprise from 35 wt % to 75 wt % of silicon, or from 40 wt % to 70 wt % silicon, or from 45 wt % to 65 wt % silicon.

Preferred composite particles include a conductive porous carbon particle framework as described above, wherein the composite particles comprise at least 80 wt %, or from 80 to 98 wt % in total of silicon and carbon.

The amount of silicon in the composite particles can be determined by elemental analysis. Preferably, elemental analysis is used to determine the weight percentage of carbon (and optionally hydrogen, nitrogen and oxygen) in the porous carbon particles alone and in the composite particles. Determining the weight percentage of carbon in the in the porous carbon particles alone takes account of the possibility that the porous carbon particles contain a minor amount of heteroatoms as well as any carbon that is present in the interlayer materials. Both measurements taken together allow the weight percentage of electroactive material relative to the porous carbon particles to be determined reliably.

The silicon content of the composite particles is preferably determined by ICP-OES (Inductively coupled plasma-optical emission spectrometry). A number of ICP-OES instruments are commercially available, such as the iCAP® 7000 series of ICP-OES analysers available from ThermoFisher Scientific. The elemental composition of the composite particles and of the porous particle framework alone (as well as the hydrogen, nitrogen and oxygen content if required) are preferably determined by IR absorption. A suitable instrument for determining carbon, hydrogen, nitrogen and oxygen content is the TruSpec® Micro elemental analyser available from Leco Corporation.

The particulate materials of the invention can be further characterised by their performance under thermogravimetric analysis (TGA) in air. Preferably the particulate material contains no more than 10% unoxidised silicon at 800° C. as determined by TGA in air with a temperature ramp rate of 10° C./min. More preferably the particulate material contains no more than 5% or no more than 2% unoxidised silicon at 800° C. as determined by TGA in air with a temperature ramp rate of 10° C./min.

The determination of the amount of unoxidised silicon is derived from the characteristic TGA trace for these materials. A mass increase at ca. 300-500° C. corresponds to initial oxidation of silicon to SiO₂, and is followed by mass loss at ca. 500-600° C. as carbon is oxidised to CO₂ gas. Above ca. 600° C., there is a further mass increase corresponding to the continued conversion of silicon to SiO₂ which increases toward an asymptotic value above 1000° C. as silicon oxidation goes to completion.

For the purposes of this analysis, it is assumed that any mass increase above 800° C. corresponds to the oxidation of silicon to SiO₂ and that the total mass at completion of oxidation is SiO₂. This allows the percentage of unoxidised silicon at 800° C. as a proportion of the total amount of silicon to be determined according to the following formula:

Z=1.875×[(M_{f}−M₈₀₀)/M_{f}]×100%

Wherein Z is the percentage of unoxidized silicon at 800° C., M_{f} is the mass of the sample at completion of oxidation and M₈₀₀ is the mass of the sample at 800° C.

Without being bound by theory, it is understood that the temperature at which silicon is oxidised under TGA corresponds broadly to the length scale of the oxide coating on the silicon due to diffusion of oxygen atoms through the oxide layer being thermally activated. The size of the silicon nanostructure and its location limit the length scale of the oxide coating thickness. Therefore it is understood that silicon deposited in pores will oxidise at a lower temperature than deposits of silicon on a particle surface due to the necessarily thinner oxide coating existing on these structures. Accordingly, preferred materials according to the invention exhibit substantially complete oxidation of silicon at low temperatures consistent with the small length scale of silicon nanostructures that are located in micropores and smaller mesopores. For the purposes of the invention, silicon oxidation at 800° C. is assumed to be silicon on the external surfaces of the porous particle framework.

The composite particles preferably have a low total oxygen content. Oxygen may be present in the composite particles for instance as part of the porous particle framework or as an oxide layer on any exposed silicon surfaces. Preferably, the surfaces of the electroactive material are passivated so as to inhibit or prevent oxide formation.

Preferably, the total oxygen content of the composite particles is less than 15 wt %, more preferably less than 10 wt %, more preferably less than 5 wt %, for example less than 2 wt %, or less than 1 wt %, or less than 0.5 wt %.

The composite particles suitably have a D₅₀ particle diameter in the range from 0.5 to 200 μm. Optionally, the D₅₀ particle diameter of the composite particles may be at least 1 μm, or at least 1.5 μm, or at least 2 μm, or at least 3 μm, or at least 4 μm, or at least 5 μm. Optionally the D₅₀ particle diameter of the composite particles may be no more than 150 μm, or no more than 100 μm, or no more than 70 μm, or no more than 50 μm, or no more than 40 μm, or no more than 30 μm, or no more than 25 μm, or no more than 20 μm, or no more than 18 μm, or no more than 15 μm, or no more than 12 μm, or no more than 10 μm.

For instance, the composite particles may have a D₅₀ particle diameter in the range from 0.5 to 200 μm, or 0.5 to 150 μm, or from 0.5 to 100 μm, or from 0.5 to 50 μm, or from 0.5 to 30 μm, or from 1 to 25 μm, or from 1 to 20 μm, or from 2 to 25 μm, or from 2 to 20 μm, or from 2 to 18 μm, or from 3 to 20 μm, or from 3 to 18 μm, or from 3 to 15 μm, or from 4 to 18 μm, or from 4 to 15 μm, or from 4 to 12 μm, or from 5 to 15 μm, or from 5 to 12 μm or from 5 to 10 μm.

Particles within these preferred size ranges and having porosity and a pore diameter distribution as set out herein are ideally suited for the preparation of composite particles for use in anodes for metal-ion batteries by a fluidized bed process. In particular, particles having these properties have good dispersibility in slurries, structural robustness, high capacity retention over repeated charge-discharge cycles, and are suitable for forming dense electrode layers of uniform thickness in the conventional thickness range from 20 to 50 μm.

The D₁₀ particle diameter of the composite particles is preferably at least 0.5 μm, or at least 0.8 μm, or at least 1 μm, or at least 1.5 μm, or at least 2 μm. By maintaining the D₁₀ particle diameter at 0.5 μm or more, the potential for undesirable agglomeration of sub-micron sized particles is reduced, resulting in improved dispersibility of the composite particles in slurries used for electrode manufacture.

The D₉₀ particle diameter of the composite particles is preferably no more than 300 μm, or no more than 250 μm, or no more than 200 μm, or no more than 150 μm, or no more than 100 μm, or no more than 80 μm, or no more than 60 μm, or no more than 40 μm, or no more than 30 μm, or no more than 25 μm, or no more than 20 μm, or no more than 15 μm. The use of larger composite particles results in non-uniform forming packing of the composite particles in electrode active layers, thus disrupting the formation of dense electrode layers, particularly electrode layers having a thickness in the range from 20 to 50 μm.

The composite particles preferably have a narrow size distribution span. For instance, the particle size distribution span (defined as (D₉₀-D₁₀)/D₅₀) is preferably 5 or less, more preferably 4 or less, more preferably 3 or less, more preferably 2 or less, and most preferably 1.5 or less. By maintaining a narrow size distribution span, efficient packing of the particles into dense electrode layers is more readily achievable.

For the avoidance of doubt, the term “particle diameter” as used herein refers to the equivalent spherical diameter (esd), i.e. the diameter of a sphere having the same volume as a given particle, wherein the particle volume is understood to include the volume of any intra-particle pores. The terms “D₅₀” and “D₅₀ particle diameter” as used herein refer to the volume-based median particle diameter, i.e. the diameter below which 50% by volume of the particle population is found. The terms “D₁₀” and “D₁₀ particle diameter” as used herein refer to the 10th percentile volume-based median particle diameter, i.e. the diameter below which 10% by volume of the particle population is found. The terms “D₉₀” and “D₉₀ particle diameter” as used herein refer to the 90th percentile volume-based median particle diameter, i.e. the diameter below which 90% by volume of the particle population is found.

Particle diameters and particle size distributions can be determined by standard laser diffraction techniques in accordance with ISO 13320:2009. Laser diffraction relies on the principle that a particle will scatter light at an angle that varies depending on the size the particle and a collection of particles will produce a pattern of scattered light defined by intensity and angle that can be correlated to a particle size distribution. A number of laser diffraction instruments are commercially available for the rapid and reliable determination of particle size distributions. Unless stated otherwise, particle size distribution measurements as specified or reported herein are as measured by the conventional Malvern Mastersizer™ 3000 particle size analyzer from Malvern Instruments. The Malvern Mastersizer™ 3000 particle size analyzer operates by projecting a helium-neon gas laser beam through a transparent cell containing the particles of interest suspended in an aqueous solution. Light rays which strike the particles are scattered through angles which are inversely proportional to the particle size and a photodetector array measures the intensity of light at several predetermined angles and the measured intensities at different angles are processed by a computer using standard theoretical principles to determine the particle size distribution. Laser diffraction values as reported herein are obtained using a wet dispersion of the particles in 2-propanol with a 5 vol % addition of the surfactant SPAN™-40 (sorbitan monopalmitate). The particle refractive index is taken to be 3.50 and the dispersant index is taken to be 1.378. Particle size distributions are calculated using the Mie scattering model.

The composite particles preferably have a BET surface area of no more than 100 m²/g, or no more than 80 m²/g, or no more than 60 m²/g, or no more than 40 m²/g, or no more than 30 m²/g, or no more than 25 m²/g, or no more than 20 m²/g, or no more than 15 m²/g, or no more than 10 m²/g. In general, a low BET surface area is preferred in order to minimize the formation of solid electrolyte interphase (SEI) layers at the surface of the composite particles during the first charge-discharge cycle of an anode. However, a BET surface area which is excessively low results in unacceptably low charging rate and capacity due to the inaccessibility of the bulk of the electroactive material to metal ions in the surrounding electrolyte. For instance, the BET surface area of the composite particles is preferably at least 0.1 m²/g, or at least 1 m²/g, or at least 2 m²/g, or at least 5 m²/g. For instance, the BET surface area may be in the range from 0.1 to 100 m²/g, or from 0.1 to 80 m²/g, or from 0.5 to 60 m²/g, or from 0.5 to 40 m²/g, or from 1 to 30 m²/g, or from 1 to 25 m²/g, or from 2 to 20 m²/g.

The composite particles may optionally include a conductive coating. For instance, the conductive coating may be a conductive pyrolytic carbon coating. In the case that one or more interlayer materials is a conductive pyrolytic carbon material, the conductive carbon coating may be the same type or a different type of conductive pyrolytic carbon to the interlayer material, for example it may be formed from different carbon-containing precursors.

Suitably a conductive pyrolytic carbon coating may be obtained by a chemical vapour deposition (CVD) method. The thickness of the carbon coating may suitably be in the range from 2 to 30 nm. Optionally, the conductive pyrolytic carbon coating may be porous and/or may only cover partially the surface of the composite particles.

A carbon coating has the advantages that it further reduces the BET surface area of the particulate material by smoothing any surface defects and by filling any remaining surface microporosity, thereby further reducing first cycle loss. In addition, a carbon coating improves the conductivity of the surface of the composite particles, reducing the need for conductive additives in the electrode composition, and also creates an optimum surface for the formation of a stable SEI layer, resulting in improved capacity retention on cycling.

The particulate material of the invention preferably has a specific charge capacity on first lithiation of 1400 to 2340 mAh/g. Preferably, silicon-containing particulate materials according to the invention have a specific charge capacity on first lithiation of 1600 to 2340 mAh/g.

In a second aspect of the invention, there is provided a process for preparing composite particles, comprising:
(a) providing a plurality of porous particles, wherein the total pore volume of pores having pore diameter in the range from 3.5 to 100 nm is P¹ cm³ per gram of the porous particles, as determined by nitrogen gas adsorption, where P¹ represents a number in the range from 0.3 to 2.4;
(b) depositing a first electroactive material layer onto the internal pore surfaces of the porous particles;
(c) forming a first interlayer material on the surface of the first electroactive material layer;
(d) depositing a second electroactive material layer onto the surface of the first interlayer material.

The process of the invention therefore provides composite particles as described above, wherein the porous particles form a framework for a multilayer coating comprising at least first and second electroactive material layers and at least a first interlayer material disposed between the first and second electroactive material layers.

In accordance with the second aspect of the invention, the porous particles used in step (a) form the porous particle framework in the particles of the first aspect of the invention. The porous particles in step (a) are therefore to be considered equivalent to the porous particle framework in the composite particles described above. Accordingly, any optional or preferred properties of the porous particle framework (including inter alia the material that forms the porous particle framework, the total pore volume of the porous particle framework, the PD₅₀ pore diameter of the porous particle framework, the pore size distribution of the porous particle framework, and the BET surface area of the porous particle framework) described above with reference to the first aspect shall also be understood to apply to the porous particles used in step (a) of the process according to the second aspect of the invention.

The porous particles used in step (a) have preferred dimensions that correspond to the preferred dimensions of the composite particles described with reference to the first aspect of the invention.

Accordingly, the porous particles used in step (a) suitably have a D₅₀ particle diameter in the range from 0.5 to 200 μm. Optionally, the D₅₀ particle diameter of the composite particles may be at least 1 μm, or at least 1.5 μm, or at least 2 μm, or at least 3 μm, or at least 4 μm, or at least 5 μm. Optionally the D₅₀ particle diameter of the porous particles may be no more than 150 μm, or no more than 100 μm, or no more than 70 μm, or no more than 50 μm, or no more than 40 μm, or no more than 30 μm, or no more than 25 μm, or no more than 20 μm, or no more than 18 μm, or no more than 15 μm, or no more than 12 μm, or no more than 10 μm.

For instance, the porous particles used in step (a) may have a D₅₀ particle diameter in the range from 0.5 to 200 μm, or from 0.5 to 150 μm, or from 0.5 to 100 μm, or from 0.5 to 50 μm, or from 0.5 to 30 μm, or from 1 to 25 μm, or from 1 to 20 μm, or from 2 to 25 μm, or from 2 to 20 μm, or from 2 to 18 μm, or from 3 to 20 μm, or from 3 to 18 μm, or from 3 to 15 μm, or from 4 to 18 μm, or from 4 to 15 μm, or from 4 to 12 μm, or from 5 to 15 μm, or from 5 to 12 μm or from 5 to 10 μm.

The D₁₀ particle diameter of the porous particles used in step (a) is preferably at least 0.5 μm, or at least 0.8 μm, or at least 1 μm, or at least 1.5 μm, or at least 2 μm. By maintaining the D₁₀ particle diameter at 0.5 μm or more, the potential for undesirable agglomeration of sub-micron sized particles is reduced, resulting in improved dispersibility of the composite particles in slurries used for electrode manufacture.

The D₉₀ particle diameter of the porous particles used in step (a) is preferably no more than 300 μm, or no more than 250 μm, or no more than 200 μm, or no more than 150 μm, or no more than 100 μm, or no more than 80 μm, or no more than 60 μm, or no more than 40 μm, or no more than 30 μm, or no more than 25 μm, or no more than 20 μm, or no more than 15 μm.

The porous particles used in step (a) preferably have a narrow size distribution span. For instance, the particle size distribution span (defined as (D₉₀-D₁₀)/D₅₀) is preferably 5 or less, more preferably 4 or less, more preferably 3 or less, more preferably 2 or less, and most preferably 1.5 or less.

Steps (b) and (d) preferably use a chemical vapour infiltration (CVI) process to deposit the first and second electroactive material layers onto the pore surfaces of the porous particles. As discussed above, chemical vapour infiltration (CVI) is a process of infiltrating a porous material with an additional phase, typically by passing a mixture of inert carrier gases and a gaseous precursor through the porous substrate at high temperature. Decomposition/reaction of the gaseous precursor on pore surfaces results in the deposition of a solid phase in the pore structure. References herein to gaseous precursors shall be understood to include vapour phase precursors that may be liquid or solid at ambient temperatures but vaporise at or below the reaction temperature.

The electroactive materials in the first and second electroactive material layers deposited in steps (b) and (d) may be the same or different, and may optionally be independently selected from elemental silicon, elemental tin, elemental germanium, elemental aluminium and mixtures and alloys thereof. A preferred electroactive material is silicon. Preferably, at least one of the first and second electroactive material layers is an elemental silicon layer. More preferably, both the first and the second electroactive material layers are elemental silicon layers.

Suitable silicon-containing precursors include silane (SiH₄), disilane (Si₂H₆), trisilane (Si₃H₈), tetrasilane (Si₄H₁₀), or chlorosilanes such as trichlorosilane (HSiCl₃) or methylchlorosilanes such as methyltrichlorosilane (CH₃SiCl₃) or dimethyldichlorosilane ((CH₃)₂SiCl₂). Preferably the silicon-containing precursor is silane.

Suitable tin-containing precursors include bis[bis(trimethylsilyl)amino]tin(II) ([[(CH₃)₃Si]₂N]₂Sn), tetraallyltin ((H₂C═CHCH₂)₄Sn), tetrakis(diethylamido)tin(IV) ([(C₂H₅)₂N]₄Sn), tetrakis(dimethylamido)tin(IV) ([CH₃)₂N]₄Sn), tetramethyltin (Sn(CH₃)₄), tetravinyltin (Sn(CH═CH₂)₄), tin(II) acetylacetonate (C₁₀H₁₄O₄Sn), trimethyl(phenylethynyl)tin (C₆H₅C≡CSn(CH₃)₃), and trimethyl(phenyl)tin (C₆H₅Sn(CH₃)₃). Preferably the tin-containing precursor is tetramethyltin.

Suitable aluminium-containing precursors include aluminium tris(2,2,6,6-tetramethyl-3,5-heptanedionate) (Al(OCC(CH₃)₃CHCOC(CH₃)₃)₃), trimethylaluminium ((CH₃)₃Al), and tris(dimethylamido)aluminium(III) (Al(N(CH₃)₂)₃). Preferably the aluminium-containing precursor is trimethylaluminium.

Suitable germanium-containing precursors include germane (GeH₄), hexamethyldigermanium ((CH₃)₃GeGe(CH₃)₃), tetramethylgermanium ((CH₃)₄Ge), tributylgermanium hydride ([CH₃(CH₂)₃]₃GeH), triethylgermanium hydride ((C₂H₅)₃GeH), and triphenylgermanium hydride ((C₆H₅)₃GeH). Preferably the germanium-containing precursor is germane.

The CVI process in steps (b) and (d) may optionally utilise a gaseous precursor of a dopant material to deposit a doped electroactive material into the micropores and/or mesopores of the porous particles. When the dopant is boron suitable precursors include borane (BH3), triisopropyl borate ([(CH₃)₂CHO]₃B), triphenylborane ((C₆H₅)₃B), and tris(pentafluorophenyl)borane (C₆F₅)₃B, preferably borane. When the dopant is phosphorous a suitable precursor is phosphine (PH₃).

Preferably, the first and second electroactive materials are both silicon. More preferably, the gaseous precursor used in steps (b) and (d) is independently selected from silane (SiH₄), disilane (Si₂H₆), trisilane (Si₃H₈), tetrasilane (Si₄H₁₀), trichlorosilane (HSiCl₃), methyltrichlorosilane (CH₃SiCl₃) and dimethyldichlorosilane ((CH₃)₂SiCl₂). More preferably, the gaseous precursor used in steps (b) and (d) to form the first and second electroactive material layers is silane (SiH₄).

The precursors in steps (b) and (d) may be used either in pure form or more usually as a diluted mixture with an inert carrier gas, such as nitrogen or argon. For instance, the precursor may be used in an amount in the range from 1 to 100 vol %, or from 1 to 50 vol %, or 2 to 40 vol %, or 5 to 30 vol %, or from 5 to 25 vol % based on the total volume of the precursor and an inert carrier gas.

The CVI process in steps (b) and (d) is suitably carried out at low partial pressure of gaseous precursor with total pressure at or close to 101.3 kPa (i.e. at atmospheric pressure, 1 atm), the remaining partial pressure made up to atmospheric pressure using an inert padding gas such as hydrogen, nitrogen or argon. The presence of oxygen should be minimised to prevent undesired oxidation of the deposited electroactive material, in accordance with conventional procedures for working in an inert atmosphere. Preferably, the oxygen content is less than 0.01 vol %, more preferably less than 0.001 vol % based on the total volume of gas used in step (b).

The temperature of the CVI process in steps (b) and (d) may in principle be any temperature that is effective to pyrolyse the precursor to form the electroactive material. Preferably, the CVI process in steps (b) and (d) is performed at temperature in the range from 300 to 700° C., or from 350 to 700° C., or from 400 to 700° C., or from 400 to 650° C., or from 400 to 600° C., or from 400 to 550° C., or from 400 to 500° C., or from 400 to 450° C., or from 450 to 500° C. More preferably, the CVI process in steps (b) and (d) is performed at a temperature in the range of 400-500° C., preferably 450-500° C.

The surface of the first electroactive material layer formed in step (b) is reactive to oxygen and forms a native oxide layer when exposed to oxygen. In the case of silicon, an amorphous silicon dioxide film is formed when a silicon surface is exposed to oxygen. Therefore, the first interlayer material may be a native oxide layer that is formed in step (c) by passivating the surface of the first electroactive material with air or another oxygen-containing gas, such as nitrous oxide. The native oxide layer on the surface of silicon may be described by the chemical formula SiOₓ, wherein 0>x≤2

The formation of the native oxide layer is exothermic and therefore requires careful process control to prevent overheating or even combustion of the particulate material during manufacture. In the case that the first interlayer material formed in step (c) is a native oxide layer, step (c) may comprise cooling the material formed in step (b) to a temperature below 300° C., preferably below 200° C., preferably below 100° C., prior to contacting the surface of the first electroactive material with the oxygen containing gas.

Instead of an oxide layer, the first interlayer material formed in step (c) may be a nitride of the first electroactive material. A nitride layer may be formed by passivating the surface of the first electroactive material with ammonia at a temperature in the range from 200-700° C., preferably from 400-700° C., more preferably from 400-600° C. to form a nitride surface (e.g. a silicon nitride surface of the formula SiNx, wherein x≤ 4/3). For example, where the passivating agent is ammonia, step (c) may be carried out at the same or similar temperature as is used to deposit the first electroactive material in step (b). As sub-stoichiometric silicon nitride is conductive, this step will also result in the formation of a conductive network that will allow for faster charging and discharge of the electroactive material.

The first interlayer material formed in step (c) may be an oxynitride layer formed on the surface of the first electroactive material layer. Step (c) may comprise exposing the surface of the first electroactive material layer to ammonia (or another nitrogen containing molecule) and oxygen gas. In the case that the first electroactive material layer comprises silicon, the interlayer material may comprise a silicon oxynitride of the formula SiOxNy, wherein 0<x<2, 0<y< 4/3, and 0<(2x+3y)≤4). The silicon oxynitride is preferably amorphous silicon oxynitride.

The first interlayer material formed in step (c) may be an amorphous or nanocrystalline carbide layer formed on the surface of the first electroactive material layer. Step (c) may comprise contacting the surface of the first electroactive material layer to carbon containing precursors, e.g. methane or ethylene, at a temperature in the range from 250 to 700° C. At lower temperatures, covalent bonds are formed between the surface of the electroactive material and the carbon-containing precursors, which are the converted to a monolayer of crystalline carbide as the temperature is increased. In the case that the first electroactive material layer comprises silicon, the interlayer material may comprise a silicon carbide of the formula SiCx, wherein 0<x≤1. The silicon carbide is preferably amorphous silicon carbide.

As a further option, the interlayer material formed in step (c) may comprise a carbon-containing organic moiety covalently bonded to the surface of the first electroactive material layer. Organic compounds containing certain functional groups such as an alkene, alkyne or carbonyl functional group, more preferably a terminal alkene, terminal alkyne or aldehyde group, are capable of passivating the surface of the first electroactive material layer and forming a covalent bond thereto. Compounds containing an active hydrogen atom, such as alcohols, thiols, amines and phosphines may also be used as passivating agents. For example, step (c) may comprise passivating the surface of the first electroactive material layer with a passivating agent selected from one or more compounds of the formula:

R¹—CH═CH—R¹; (i)

R¹—C≡C—R¹; (ii)

O═CH—R¹; and (iii)

wherein each R¹ independently represents H or an unsubstituted or substituted aliphatic or aromatic hydrocarbyl group having from 1 to 20 carbon atoms, preferably from 2 to 10 carbon atoms, or wherein two R groups in formula (i) form an unsubstituted or substituted hydrocarbyl ring structure comprising from 3 to 8 carbon atoms in the ring.

Particularly preferred passivating agents include one or more compounds of the formulae:

CH₂═CH—R¹; and (i)

HC≡C—R¹; (ii)

wherein R¹ is as defined above. Preferably, R¹ is unsubstituted.

Particular examples of suitable organic compounds that may be used to form the modifier material domains via passivation of the surface of the electroactive material domains include ethylene, propylene, 1-butene, butadiene, 1-pentene, 1,4-pentadiene, 1-hexene, 1-octene, styrene, divinylbenzene, acetylene, phenylacetylene, norbornene, norbornadiene, bicyclo[2.2.2]oct-2-ene, camphene, 3-carene, sabinene, thujene, pinene, limonene, acetylene, phenylacetylene, anthraquinone, anthrone, and camphor. Mixtures of different passivating agents may also be used.

Further examples of organic compounds that may be used to form the first interlayer material via passivation of the surface of the first electroactive material layer include compounds including an active hydrogen atom bonded to oxygen, nitrogen, sulphur or phosphorus. For example, the passivating agent may be an alcohol, amine, thiol or phosphine. Reaction of the group —XH with hydride groups at the surface of the electroactive material is understood to result in elimination of H₂ and the formation of a direct bond between X and the electroactive material surface.

Suitable passivating agents in this category include compounds of the formula

HX—R², (iv)

HX—C(O)—R¹, (v)

wherein X represents O, S, NR or PR, and wherein each R¹ is independently as defined above and R² represents an unsubstituted or substituted aliphatic or aromatic hydrocarbyl group having from 1 to 20 carbon atoms, or R¹ and R² together form an unsubstituted or substituted hydrocarbyl ring structure comprising from 3 to 8 carbon atoms in the ring.

Preferably X represents O or NH.

Preferably R² represents an optionally substituted aliphatic or aromatic group having from 2 to 10 carbon atoms. Amine groups may also be incorporated into a 4-10 membered aliphatic or aromatic ring structure, as in pyrrolidine, pyrrole, imidazole, piperazine, indole, or purine.

Examples of suitable compounds in this category include borneol, terpineol, sucrose, thiophenol, and aniline. Mixtures of different passivating agents may also be used.

A covalently bound organic interlayer material may be formed by passivating the surface of the first electroactive material with an organic passivating agent as described above at a temperature in the range of from 200-700° C., preferably from 400-700° C., more preferably from 400-600° C. For example, where organic passivating agent is used to form the first interlayer material, step (c) may be carried out at the same or similar temperature as is used to deposit the first electroactive material in step (b).

As a further option, an amorphous or nanocrystalline carbide layer may be formed by contacting the surface of the first electroactive material with carbon containing precursors, e.g. methane or ethylene, at a temperature in the range from 250 to 700° C. At lower temperatures, covalent bonds are formed between the surface of the electroactive material and the carbon-containing precursors, which are the converted to a monolayer of crystalline silicon carbide as the temperature is increased.

As a further option, step (c) may comprise forming a layer of a conductive pyrolytic carbon material as the first interlayer material. A pyrolytic carbon may also be obtained by a chemical vapour infiltration (CVI) method, i.e. by thermal decomposition of a volatile carbon-containing gas (such as a hydrocarbon) onto the surface of the silicon-containing composite particles.

Suitable precursors for forming a conductive pyrolytic carbon material include polycyclic hydrocarbons comprising from 10 to 25 carbon atoms and optionally from 1 to 3 heteroatoms, optionally wherein the polyaromatic hydrocarbon is selected from naphthalene, substituted naphthalenes such as di-hydroxynaphthalene, anthracene, tetracene, pentacene, fluorene, acenapthene, phenanthrene, fluoranthrene, pyrene, chrysene, perylene, coronene, fluorenone, anthraquinone, anthrone and alkyl-substituted derivatives thereof. Further suitable pyrolytic carbon precursors also include bicyclic monoterpenoids, optionally wherein the bicyclic monoterpenoid is selected from camphor, borneol, eucalyptol, camphene, careen, sabinene, thujene, α-terpinene and pinene. Further suitable pyrolytic carbon precursors include C₂-C₁₀ hydrocarbons, optionally wherein the hydrocarbons are selected from alkanes, alkenes, alkynes, cycloalkanes, cycloalkenes, and arenes, for example methane, ethylene, propylene, butane, butadiene, 1-pentene, 1,4-pentadiene, 1-hexene, 1-octene, limonene, styrene, cyclohexane, cyclohexene, and acetylene divinylbenzene, norbornene, norbornadiene, cyclopentadiene, dicyclopentadiene, bicyclo[2.2.2]oct-2-ene. Other suitable pyrolytic carbon precursors include phthalocyanine, sucrose, starches, graphene oxide, reduced graphene oxide, pyrenes, perhydropyrene, triphenylene, tetracene, benzopyrene, perylenes, coronene, and chrysene. A preferred carbon precursor is acetylene.

The pyrolytic carbon precursors used in step (c) may be used in pure form, or diluted mixture with an inert carrier gas, such as nitrogen or argon. For instance, the pyrolytic carbon precursor may be used in an amount in the range from 0.1 to 50 vol %, or 0.5 to 20 vol %, or 1 to 10 vol %, or 1 to 5 vol % based on the total volume of the precursor and the inert carrier gas.

The formation of a conductive pyrolytic carbon layer in step (c) may optionally be carried out following passivation of the surface of the first electroactive material layer by one of the processes described above. Accordingly, the interlayer material formed in step (c), may comprise both a passivation layer on the surface of the first electroactive material layer and a conductive pyrolytic carbon layer.

In the case that the surface of the first electroactive material layer is passivated with an organic compound (particularly an alkene or alkyne) to form an organic moiety covalently bonded to the surface of the first electroactive material layer, the same compound may be used for the passivation step and as the pyrolytic carbon precursor. The covalently bound organic moiety therefore provides a substrate for the growth of the conductive pyrolytic carbon interlayer material.

As a further option, step (c) may comprise forming a layer of a conductive metal as the first interlayer material. A conductive metal layer may also be obtained by a chemical vapour infiltration (CVI) method. Examples of suitable conductive metals include, silver, gold, copper and titanium.

The formation of a conductive metal interlayer material in step (c) may optionally be carried out following passivation of the surface of the first electroactive material layer by one of the processes described above. Accordingly, the interlayer material formed in step (c), may comprise both a passivation layer on the surface of the first electroactive material layer and a conductive metal layer.

As a further option, step (c) may comprise forming a layer of a lithium-ion permeable solid electrolyte as the first interlayer material. A lithium-ion permeable solid electrolyte may be deposited in step (c) by a similar CVI process as is used in step (b). For example, a lithium phosphate solid electrolyte may be deposited in step (c) by the use of an atmosphere of tert-butyllithium and trimethylphosphate. The CVI of a lithium-ion permeable solid electrolyte in step (c) may suitably be carried out at a temperature of up to 700° C., or no more than 650° C., or no more than 600° C. or no more than 550° C., or no more than 500° C. The minimum temperature in step (c) will depend on the type of a lithium-ion permeable solid electrolyte that is used. Preferably, the temperature in step (c) is at least 300° C., or at least 350° C., or at least 400° C., or at least 450° C. For example, the temperature in step (c) may be in the range of 400-500° C.

Steps (c) and (d) are optionally repeated one or more times to form a particulate material, comprising three or more electroactive material layers with multiple interlayer materials disposed between each of the adjacent electroactive material layers. For example, steps (c) and (d) are optionally repeated one or more times to form a particulate material, comprising n electroactive material layers and (n−1) interlayer materials disposed between each of the electroactive material layers, wherein n is an integer from 3 to 20, or from 3 to 15, or from 3 to 12, or from 3 to 10, or from 4 to 10, or from 5 to 8.

Each repetition of step (d) may be used to form an electroactive material layer which may be the same as, or different from, any other electroactive material layer, and each repetition may independently have any of the features of step (d) as described above. Preferably, each of the n electroactive material layers comprises the same electroactive material. More preferably, each of the n electroactive material layers formed in each repetition of step (d) is a silicon layer.

Each repetition of step (c) may likewise be used to form an interlayer material which may be the same as, or different from, any other interlayer material, and each repetition may independently have any of the features of step (c) as described above. Preferably, each of the (n−1) electroactive material layers comprises the same interlayer material.

The process of the invention may optionally include a further step (e), comprising forming a coating layer on the surface of the final electroactive material layer to be deposited (i.e. the layer formed in the final instance of step (d)). The coating layer formed in step (e) may be formed in an analogous manner to the interlayer formed in step (c), and any of the interlayer materials described above may also be used to form the coating layer in step (e).

The process of the invention may be carried out in any reactor that is capable of contacting the porous particles with a gas comprising precursors of the electroactive materials and interlayer materials. Suitable reactor types include a static furnace, a rotary kiln, or a fluidized bed reactor (including spouted bed reactor).

Suitably, each of steps (b), (c), (d) and optional step (e) are carried out by contacting the porous particles with a continuous flow of a gas comprising the respective precursors of the electroactive materials, interlayer materials, and optional coating materials for a period of time sufficient to form the desired layer thickness. By cycling the atmosphere in the reactor between the different precursors, the multilayer structure may be formed layer-by-layer until the required number of layers is formed.

Alternatively, each of steps (b), (c), (d) and optional step (e) may be carried out by contacting the porous particles with a fixed charge of a gas comprising the respective precursors in a batch reactor. The use of a batch reactor has the advantage that, by controlling the volume of precursor gases supplied to the reactor in each charge, the amount of electroactive materials, interlayer materials and coating materials may be precisely controlled. A batch reactor may optionally comprise means for agitating the porous particles.

The reactor is preferably flushed with a suitable inert gas between each successive CVI step. The inert gas used to flush the reactor is preferably the same inert gas as is used as the carrier gas for the respective precursors of the electroactive materials, interlayer materials, and optional coating materials.

In a third aspect of the invention, there is provided a composition comprising a particulate material according to the first aspect of the invention and at least one other component, optionally a component selected from: (i) a binder; (ii) a conductive additive; and (iii) an additional particulate electroactive material. The composition according to the third aspect of the invention is useful as an electrode composition, and thus may be used to form the active layer of an electrode.

The composition preferably comprises from 1 to 95 wt %, or from 2 to 90 wt %, or from 5 to 85 wt %, or from 10 to 80 wt % of the particulate material according to the first aspect of the invention, based on the total dry weight of the composition.

The composition may be a hybrid electrode composition which comprises the composite particles and at least one additional particulate electroactive material. Examples of additional particulate electroactive materials include graphite, hard carbon, silicon, tin, germanium, aluminium and lead. The at least one additional particulate electroactive material is preferably selected from graphite and hard carbon, and most preferably the at least one additional particulate electroactive material is graphite.

In the case of a hybrid electrode composition, the composition preferably comprises from 3 to 60 wt %, or from 3 to 50 wt %, or from 5 to 50 wt %, or from 10 to 50 wt %, or from 15 to 50 wt %, of the composite particles, based on the total dry weight of the composition.

The at least one additional particulate electroactive material is suitably present in an amount of from 20 to 95 wt %, or from 25 to 90 wt %, or from 30 to 75 wt % of the at least one additional particulate electroactive material.

The at least one additional particulate electroactive material preferably has a D₅₀ particle diameter in the range from 10 to 50 μm, preferably from 10 to 40 μm, more preferably from 10 to 30 μm and most preferably from 10 to 25 μm, for example from 15 to 25 μm.

The D₁₀ particle diameter of the at least one additional particulate electroactive material is preferably at least 5 μm, more preferably at least 6 μm, more preferably at least 7 μm, more preferably at least 8 μm, more preferably at least 9 μm, and still more preferably at least 10 μm.

The D₉₀ particle diameter of the at least one additional particulate electroactive material is preferably up to 100 μm, more preferably up to 80 μm, more preferably up to 60 μm, more preferably up to 50 μm, and most preferably up to 40 μm.

The at least one additional particulate electroactive material is preferably selected from carbon-comprising particles, graphite particles and/or hard carbon particles, wherein the graphite and hard carbon particles have a D₅₀ particle diameter in the range from 10 to 50 μm. Still more preferably, the at least one additional particulate electroactive material is selected from graphite particles, wherein the graphite particles have a D₅₀ particle diameter in the range from 10 to 50 μm.

The composition may also be a non-hybrid (or “high loading”) electrode composition which is substantially free of additional particulate electroactive materials. In this context, the term “substantially free of additional particulate electroactive materials” should be interpreted as meaning that the composition comprises less than 15 wt %, preferably less than 10 wt %, preferably less than 5 wt %, preferably less than 2 wt %, more preferably less than 1 wt %, more preferably less than 0.5 wt % of any additional electroactive materials (i.e. additional materials which are capable of inserting and releasing metal ions during the charging and discharging of a battery), based on the total dry weight of the composition.

A “high-loading” electrode composition of this type preferably comprises at least 50 wt %, or at least 60 wt %, or at least 70 wt %, or at least 80 wt %, or at least 90 wt % of the composite particles obtained according to the first aspect of the invention, based on the total dry weight of the composition.

The composition may optionally comprise a binder. A binder functions to adhere the composition to a current collector and to maintain the integrity of the composition. Examples of binders which may be used in accordance with the present invention include polyvinylidene fluoride (PVDF), polyacrylic acid (PAA) and alkali metal salts thereof, modified polyacrylic acid (mPAA) and alkali metal salts thereof, carboxymethylcellulose (CMC), modified carboxymethylcellulose (mCMC), sodium carboxymethylcellulose (Na-CMC), polyvinylalcohol (PVA), alginates and alkali metal salts thereof, styrene-butadiene rubber (SBR) and polyimide. The composition may comprise a mixture of binders. Preferably, the binder comprises polymers selected from polyacrylic acid (PAA) and alkali metal salts thereof, and modified polyacrylic acid (mPAA) and alkali metal salts thereof, SBR and CMC.

The binder may suitably be present in an amount of from 0.5 to 20 wt %, preferably 1 to 15 wt %, preferably 2 to 10 wt % and most preferably 5 to 10 wt %, based on the total dry weight of the composition.

The binder may optionally be present in combination with one or more additives that modify the properties of the binder, such as cross-linking accelerators, coupling agents and/or adhesive accelerators.

The composition may optionally comprise one or more conductive additives. Preferred conductive additives are non-electroactive materials that are included so as to improve electrical conductivity between the electroactive components of the composition and between the electroactive components of the composition and a current collector. The conductive additives may be selected from carbon black, carbon fibers, carbon nanotubes, graphene, acetylene black, ketjen black, metal fibers, metal powders and conductive metal oxides. Preferred conductive additives include carbon black and carbon nanotubes.

The one or more conductive additives may suitably be present in a total amount of from 0.5 to 20 wt %, preferably 1 to 15 wt %, preferably 2 to 10 wt % and most preferably 5 to 10 wt %, based on the total dry weight of the composition.

In a fourth aspect, the invention provides an electrode comprising a particulate material according to the first aspect of the invention in electrical contact with a current collector. The particulate material used to prepare the electrode of the fourth aspect of the invention may be in the form of a composition according to the third aspect of the invention.

As used herein, the term current collector refers to any conductive substrate that is capable of carrying a current to and from the electroactive particles in the composition. Examples of materials that can be used as the current collector include copper, aluminium, stainless steel, nickel, titanium and sintered carbon. Copper is a preferred material. The current collector is typically in the form of a foil or mesh having a thickness of between 3 to 500 μm. The particulate materials of the invention may be applied to one or both surfaces of the current collector to a thickness which is preferably in the range from 10 μm to 1 mm, for example from 20 to 500 μm, or from 50 to 200 μm.

The electrode of the fourth aspect of the invention may be fabricated by combining the particulate material of the invention with a solvent and optionally one or more viscosity modifying additives to form a slurry. The slurry is then cast onto the surface of a current collector and the solvent is removed, thereby forming an electrode layer on the surface of the current collector. Further steps, such as heat treatment to cure any binders and/or calendaring of the electrode layer may be carried out as appropriate. The electrode layer suitably has a thickness in the range from 20 μm to 2 mm, preferably 20 μm to 1 mm, preferably 20 μm to 500 μm, preferably 20 μm to 200 μm, preferably 20 μm to 100 μm, preferably 20 μm to 50 μm.

Alternatively, the slurry may be formed into a freestanding film or mat comprising the particulate material of the invention, for instance by casting the slurry onto a suitable casting template, removing the solvent and then removing the casting template. The resulting film or mat is in the form of a cohesive, freestanding mass that may then be bonded to a current collector by known methods.

The electrode of the fourth aspect of the invention may be used as the anode of a metal-ion battery. Thus, in a fifth aspect, the invention provides a rechargeable metal-ion battery comprising an anode, the anode comprising an electrode as described above, a cathode comprising a cathode active material capable of releasing and reabsorbing metal ions; and an electrolyte between the anode and the cathode.

The metal ions are preferably lithium ions. More preferably, the rechargeable metal-ion battery of the invention is a lithium-ion battery, and the cathode active material is capable of releasing and accepting lithium ions.

The cathode active material is preferably a metal oxide-based composite. Examples of suitable cathode active materials include LiCoO₂, LiCo_{0.99}Al_{0.01}O₂, LiNiO₂, LiMnO₂, LiCo_{0.5}Ni_{0.5}O₂, LiCo_{0.7}Ni_{0.3}O₂, LiCo_{0.8}Ni_{0.2}O₂, LiCo_{0.82}Ni_{0.18}O₂, LiCo_{0.8}Ni_{0.15}Al_{0.05}O₂, LiNi_{0.4}Co_{0.3}Mn_{0.3}O₂ and LiNi_{0.33}Co_{0.33}Mn_{0.34}O₂. The cathode current collector is generally of a thickness of between 3 to 500 μm. Examples of materials that can be used as the cathode current collector include aluminium, stainless steel, nickel, titanium and sintered carbon.

The electrolyte is suitably a non-aqueous electrolyte containing a metal salt, e.g. a lithium salt, and may include, without limitation, non-aqueous electrolytic solutions, solid electrolytes and inorganic solid electrolytes. Examples of non-aqueous electrolyte solutions that can be used include non-protic organic solvents such as propylene carbonate, ethylene carbonate, butylene carbonates, dimethyl carbonate, diethyl carbonate, gamma butyrolactone, 1,2-dimethoxyethane, 2-methyltetrahydrofuran, di methylsulfoxide, 1,3-dioxolane, formamide, dimethylformamide, acetonitrile, nitromethane, methylformate, methyl acetate, phosphoric acid triesters, trimethoxymethane, sulfolane, methyl sulfolane and 1,3-dimethyl-2-imidazolidinone.

Examples of organic solid electrolytes include polyethylene derivatives polyethyleneoxide derivatives, polypropylene oxide derivatives, phosphoric acid ester polymers, polyester sulfide, polyvinylalcohols, polyvinylidine fluoride and polymers containing ionic dissociation groups.

Examples of inorganic solid electrolytes include nitrides, halides and sulfides of lithium salts such as Li₅NI₂, Li₃N, LiI, LiSiO₄, Li₂SiS₃, Li₄SiO₄, LiOH and Li₃PO₄.

The lithium salt is suitably soluble in the chosen solvent or mixture of solvents. Examples of suitable lithium salts include LiCI, LiBr, LiI, LiClO₄, LiBF₄, LiBC₄O₈, LiPF₆, LiCF₃SO₃, LiAsF₆, LiSbF₆, LiAlCl₄, CH₃SO₃Li and CF₃SO₃Li.

Where the electrolyte is a non-aqueous organic solution, the metal-ion battery is preferably provided with a separator interposed between the anode and the cathode. The separator is typically formed of an insulating material having high ion permeability and high mechanical strength. The separator typically has a pore diameter of between 0.01 and 100 μm and a thickness of between 5 and 300 μm. Examples of suitable electrode separators include a micro-porous polyethylene film.

The separator may be replaced by a polymer electrolyte material and in such cases the polymer electrolyte material is present within both the composite anode layer and the composite cathode layer. The polymer electrolyte material can be a solid polymer electrolyte or a gel-type polymer electrolyte.

In a sixth aspect, the invention provides the use of a particulate material according to the first aspect of the invention as an anode active material. Optionally, the particulate material is in the form of a composition according to the third aspect of the invention.

Further disclosure of the invention is provided by way of the following numbered statements:

1. A particulate material consisting of a plurality of composite particles, wherein the composite particles comprise:
(a) a porous particle framework, wherein the total pore volume of pores having pore diameter in the range from 3.5 to 100 nm is P¹ cm³ per gram of the porous particle framework, as determined by nitrogen gas adsorption, where P¹ represents a number in the range from 0.3 to 2.4;
(b) a multilayer coating disposed on the internal pore surfaces of the porous particle framework, wherein the multilayer coating comprises at least:
   (i) a first electroactive material layer;
   (ii) a second electroactive material layer; and
   (iii) a first interlayer material disposed between the first and second electroactive material layers.

2. A particulate material according to statement 1, wherein the porous particle framework is a conductive porous particle framework.

3. A particulate material according to statement 2, wherein the conductive porous particle framework is a conductive porous carbon particle framework.

4. A particulate material according to statement 3, wherein the conductive porous carbon particle framework comprises at least 80 wt % carbon, or at least 85 wt % carbon, or at least 90 wt % carbon, or at least 95 wt % carbon.

5. A particulate material according to any preceding statement, wherein P¹ is in the range from 0.6 to 2.4, or from 0.7 to 2.4, or from 0.8 to 2.3, or from 0.9 to 2.2, or from 0.95 to 2.1, or from 1 to 2, or from 1.05 to 1.95, or from 1.1 to 1.9, or from 1.15 to 1.85, or from 1.2 to 1.8.

6. A particulate material according to any preceding statement, wherein the volume fraction of pores having a pore diameter in the range from 5 to 60 nm is at least 50 vol %, or at least 55 vol %, or at least 60 vol %, or at least 65 vol %, or at least 70 vol %, or at least 75 vol %, or at least 80 vol %, or at least 85 vol %, or at least 90 vol %, based on the total pore volume of pores having pore diameter in the range from 3.5 to 100 nm in the porous particle framework.

7. A particulate material according to statement 6, wherein the volume fraction of pores having a pore diameter in the range from 10 to 50 nm is at least 50 vol %, or at least 55 vol %, or at least 60 vol %, or at least 65 vol %, or at least 70 vol %, or at least 75 vol %, or at least 80 vol %, or at least 85 vol %, or at least 90 vol %, based on the total pore volume of pores having pore diameter in the range from 3.5 to 100 nm in the porous particle framework.

8. A particulate material according to any preceding statement, wherein the total volume of pores having diameter less than 3.5 nm in the porous particle framework, as determined by nitrogen gas adsorption, is P² cm³/g, wherein P² represents a number having a value of less than 0.5, or less than 0.45, or less than 0.4, or less than 0.35, or less than 0.3, or less than 0.25, or less than 0.2, or less than 0.15, or less than 0.1.

9. A particulate material according to any preceding statement, wherein the total volume of pores having diameter less than 3.5 nm in the porous particle framework, as determined by nitrogen gas adsorption, is P² cm³/g, wherein P² is no more than [1×P¹], or no more than [0.8×P¹], or no more than [0.6×P¹], or no more than [0.5×P¹], or no more than [0.4×P¹], or no more than [0.3×P¹], or no more than [0.2×P¹], or no more than [0.1×P¹].

10. A particulate material according to any preceding statement, wherein the porous particle framework has a BET surface area in the range from 250 m²/g to 2,500 m²/g, or from 500 m²/g to 2,500 m²/g, or from 750 m²/g to 2,000 m²/g, or from 750 m²/g to 1,750 m²/g, or from 750 m²/g to 1,500 m²/g, or from 1,000 to 2,000 m²/g, or from 1,000 m²/g to 1,750 m²/g, or from 1,000 m²/g to 1,500 m²/g, or from 1,250 m²/g to 2,000 m²/g, or from 1,250 m²/g to 1,750 m²/g, or from 250 m²/g to 2,000 m²/g, or from 250 m²/g to 1,750 m²/g, or from 500 m²/g to 1,500 m²/g.

11. A particulate material according to any preceding statement, wherein the first and second electroactive material layers independently comprise an electroactive material selected from elemental silicon, elemental tin, elemental germanium, elemental aluminium, and mixtures and alloys thereof.

12. A particulate material according to statement 11, wherein the first and second electroactive material layers both comprise or consist of elemental silicon.

13. A particulate material according to any preceding statement, wherein the first interlayer material comprises carbon, nitrogen, oxygen or a conductive metallic element or alloy.

14. A particulate material according to statement 13, wherein the first interlayer material comprises or consists of a passivation layer formed on the surface of the first electroactive material layer, wherein the passivation layer is an oxide, nitride, oxynitride or carbide of the first electroactive material, preferably wherein the first interlayer material is an oxide selected from SiOₓ, wherein 0<x≤2 or a nitride selected from SiNₓ, wherein 0<x≤ 4/3, or a carbide selected from SiCₓ, wherein 0<x≤1.

15. A particulate material according to statement 13, wherein the first interlayer material comprises or consists of a passivation layer formed on the surface of the first electroactive material layer, wherein the passivation layer comprises a carbon-containing organic moiety covalently bonded to the surface of the first electroactive material layer.

16. A particulate material according any of statements 1 to 15, wherein the first interlayer material comprises a conductive pyrolytic carbon material.

17. A particulate material according any of statements 1 to 15, wherein the first interlayer material comprises a conductive metal layer.

18. A particulate material according to any of statements 1 to 15, wherein the first interlayer material comprises a lithium-ion permeable solid electrolyte.

19. A particulate material according to any preceding statement, wherein the multilayer coating comprises n electroactive material layers and (n−1) interlayer materials disposed between each of the electroactive material layers, wherein n is an integer from 3 to 20, or from 3 to 15, or from 4 to 12, or from 4 to 10, or from 5 to 10, or from 5 to 8.

20. A particulate material according to statement 19, wherein each of the n electroactive materials is independently as defined in statement 11, preferably wherein each of the n electroactive materials is the same electroactive material, more preferably wherein each of the n electroactive materials is silicon.

21. A particulate material according to statement 19 or statement 20, wherein each of the (n−1) interlayer materials is independently as defined in any of statements 13 to 18, optionally wherein each of the (n−1) interlayer materials is the same interlayer material.

22. A particulate material according to any preceding statement, further comprising:
(iv) a coating layer disposed on the surface of the outermost electroactive material layer,

optionally wherein the coating layer is formed from any of the materials described for the interlayer material in statements 13 to 18.

23. A particulate material according to any preceding statement, wherein the amount of electroactive material in the composite particles of the invention is selected such that at least 25% and up to 80% of the internal pore volume of the porous particle framework is occupied by the electroactive material(s) and interlayer material(s).

24. A particulate material according to any preceding statement, wherein the composite particles comprise from 35 wt % to 75 wt % of silicon, or from 40 wt % to 70 wt % silicon, or from 45 wt % to 65 wt % silicon.

25. A particulate material according to any preceding statement, wherein the composite particles comprise at least 80 wt %, or from 80 to 98 wt % in total of silicon and carbon.

26. A particulate material according to any preceding statement, wherein at least 85 wt %, more preferably at least 90 wt %, more preferably at least 95 wt %, more preferably at least 98 wt % of the electroactive material mass in the composite particles is located within the internal pore volume of the porous particle framework.

27. A particulate material according to any preceding statement, wherein the total oxygen content of the composite particles is less than 15 wt %, or less than 10 wt %, or less than 5 wt %, or less than 2 wt %, or less than 1 wt %, or less than 0.5 wt %.

28. A particulate material according to any preceding statement, wherein the composite particles have a D₅₀ particle diameter in the range from 0.5 to 200 μm, or from 0.5 to 150 μm, or from 0.5 to 100 μm, or from 0.5 to 50 μm, or from 0.5 to 30 μm, or from 1 to 25 μm, or from 1 to 20 μm, or from 2 to 25 μm, or from 2 to 20 μm, or from 2 to 18 μm, or from 3 to 20 μm, or from 3 to 18 μm, or from 3 to 15 μm, or from 4 to 18 μm, or from 4 to 15 μm, or from 4 to 12 μm, or from 5 to 15 μm, or from 5 to 12 μm or from 5 to 10 μm.

29. A particulate material according to any preceding statement, wherein the composite particles have a BET surface area in the range from 0.1 to 100 m²/g, or from 0.1 to 80 m²/g, or from 0.5 to 60 m²/g, or from 0.5 to 40 m²/g, or from 1 to 30 m²/g, or from 1 to 25 m²/g, or from 2 to 20 m²/g.

30. A particulate material according to any preceding statement, having specific capacity on lithiation in the range from 1400 to 2340 mAh/g, preferably from 1600 to 2340 mAh/g.

31. A process for preparing composite particles, comprising:
(a) providing a plurality of porous particles, wherein the total pore volume of pores having pore diameter in the range from 3.5 to 100 nm is P¹ cm³ per gram of the porous particles, as determined by nitrogen gas adsorption, where P¹ represents a number in the range from 0.3 to 2.4;
(b) depositing a first electroactive material layer onto the internal pore surfaces of the porous particles;
(c) forming a first interlayer material on the surface of the first electroactive material layer;
(d) depositing a second electroactive material layer onto the surface of the first interlayer material.

32. A process according to statement 31, wherein the porous particles are conductive porous particles.

33. A process according to statement 32, wherein the conductive porous particles are conductive porous carbon particles.

34. A process according to statement 33, wherein the conductive porous carbon particles comprise at least 80 wt % carbon, or at least 85 wt % carbon, or at least 90 wt % carbon, or at least 95 wt % carbon.

35. A process according to any of statements 31 to 34, wherein P¹ is in the range from 0.6 to 2.4, or from 0.7 to 2.4, or from 0.8 to 2.3, or from 0.9 to 2.2, or from 0.95 to 2.1, or from 1 to 2, or from 1.05 to 1.95, or from 1.1 to 1.9, or from 1.15 to 1.85, or from 1.2 to 1.8.

36. A process according to any of statements 31 to 35, wherein the volume fraction of pores having a pore diameter in the range from 5 to 60 nm is at least 50 vol %, or at least 55 vol %, or at least 60 vol %, or at least 65 vol %, or at least 70 vol %, or at least 75 vol %, or at least 80 vol %, or at least 85 vol %, or at least 90 vol %, based on the total pore volume of pores having pore diameter in the range from 3.5 to 100 nm in the porous particles.

37. A process according to statement 36, wherein the volume fraction of pores having a pore diameter in the range from 10 to 50 nm is at least 50 vol %, or at least 55 vol %, or at least 60 vol %, or at least 65 vol %, or at least 70 vol %, or at least 75 vol %, or at least 80 vol %, or at least 85 vol %, or at least 90 vol %, based on the total pore volume of pores having pore diameter in the range from 3.5 to 100 nm in the porous particles.

38. A process according to any of statements 31 to 37, wherein the total volume of pores having diameter less than 3.5 nm in the porous particles is defined as P² cm³/g, wherein P² represents a number having a value of less than 0.5, or less than 0.45, or less than 0.4, or less than 0.35, or less than 0.3, or less than 0.25, or less than 0.2, or less than 0.15, or less than 0.1, as determined by nitrogen gas adsorption.

39. A process according to any of statements 31 to 38, wherein the total volume of pores having diameter less than 3.5 nm in the porous particles, as determined by nitrogen gas adsorption, is defined as P² cm³/g, wherein P² is no more than [1×P¹], or no more than [0.8×P¹], or no more than [0.6×P¹], or no more than [0.5×P¹], or no more than [0.4×P¹], or no more than [0.3×P¹], or no more than [0.2×P¹], or no more than [0.1×P¹].

40. A process according to any of statements 31 to 39, wherein the porous particles have a BET surface area in the range from 250 m²/g to 2,500 m²/g, or from 500 m²/g to 2,500 m²/g, or from 750 m²/g to 2,000 m²/g, or from 750 m²/g to 1,750 m²/g, or from 750 m²/g to 1,500 m²/g, or from 1,000 to 2,000 m²/g, or from 1,000 m²/g to 1,750 m²/g, or from 1,000 m²/g to 1,500 m²/g, or from 1,250 m²/g to 2,000 m²/g, or from 1,250 m²/g to 1,750 m²/g, or from 250 m²/g to 2,000 m²/g, or from 250 m²/g to 1,750 m²/g, or from 500 m²/g to 1,500 m²/g.

41. A process according to any of statements 31 to 40, wherein the porous particles have a D₅₀ particle diameter in the range from 0.5 to 200 μm, or from 0.5 to 150 μm, or from 0.5 to 100 μm, or from 0.5 to 50 μm, or from 0.5 to 30 μm, or from 1 to 25 μm, or from 1 to 20 μm, or from 2 to 25 μm, or from 2 to 20 μm, or from 2 to 18 μm, or from 3 to 20 μm, or from 3 to 18 μm, or from 3 to 15 μm, or from 4 to 18 μm, or from 4 to 15 μm, or from 4 to 12 μm, or from 5 to 15 μm, or from 5 to 12 μm or from 5 to 10 μm.

42. A process according to any of statements 31 to 41, wherein the first and second electroactive materials are independently selected from elemental silicon, elemental tin, elemental germanium, elemental aluminium and mixtures and alloys thereof.

43. A process according to any of statements 31 to 42, wherein at least one of the first and second electroactive materials is deposited by a chemical vapour infiltration (CVI) process using a gaseous precursor of the first and/or second electroactive material.

44. A process according to statement 43, wherein the gaseous precursor of the first and second electroactive materials is independently selected from silane (SiH₄), disilane (Si₂H₆), trisilane (Si₃H₈), tetrasilane (Si₄H₁₀), trichlorosilane (HSiCl₃) such as methyltrichlorosilane (CH₃SiCl₃) or dimethyldichlorosilane ((CH₃)₂SiCl₂), bis[bis(trimethylsilyl)amino]tin(II) ([[(CH₃)₃Si]₂N]₂Sn), tetraallyltin ((H₂C═CHCH₂)₄Sn), tetrakis(diethylamido)tin(IV) ([(C₂H₅)₂N]₄Sn), tetrakis(dimethylamido)tin(IV) ([(CH₃)₂N]₄Sn), tetramethyltin (Sn(CH₃)₄), tetravinyltin (Sn(CH═CH₂)₄), tin(II) acetylacetonate (C₁₀H₁₄O₄Sn), trimethyl(phenylethynyl)tin (C₆H₅C≡CSn(CH₃)₃), trimethyl(phenyl)tin (C₆H₅Sn(CH₃)₃), aluminium tris(2,2,6,6-tetramethyl-3,5-heptanedionate) (Al(OCC(CH₃)₃CHCOC(CH₃)₃)₃), trimethylaluminium ((CH₃)₃Al), tris(dimethylamido)aluminium(III) (Al(N(CH₃)₂)₃), germane (GeH₄), hexamethyldigermanium ((CH₃)₃GeGe(CH₃)₃), tetramethylgermanium ((CH₃)₄Ge), tributylgermanium hydride ([CH₃(CH₂)₃]₃GeH), triethylgermanium hydride ((C₂H₅)₃GeH), and triphenylgermanium hydride ((C₆H₅)₃GeH).

45. A process according to statement 42 or statement 44, wherein the first and second electroactive materials are both elemental silicon, optionally wherein the gaseous precursor of the first and second electroactive materials is independently selected from silane (SiH₄), disilane (Si₂H₆), trisilane (Si₃H₈), tetrasilane (Si₄H₁₀), trichlorosilane (HSiCl₃), methyltrichlorosilane (CH₃SiCl₃) and dimethyldichlorosilane ((CH₃)₂SiCl₂), optionally wherein the gaseous precursor of the first and second electroactive materials is silane (SiH₄).

46. A process according to any of statements 43 to 45, wherein steps (b) and (d) independently comprise contacting the plurality of porous particles with a gas comprising from 1 to 100 vol %, or from 1 to 50 vol %, or from 2 to 40 vol %, or from 5 to 30 vol %, or from 5 to 25 vol % of the respective gaseous precursor.

47. A process according to any of statements 31 to 46, wherein steps (b) and (d) are independently carried out at a temperature in the range from 300 to 700° C., or from 350 to 700° C., or from 400 to 700° C., or from 400 to 650° C., or from 400 to 600° C., or from 400 to 550° C., or from 400 to 500° C., or from 400 to 450° C., or from 450 to 500° C.

48. A process according to any of statements 31 to 47, wherein step (c) comprises passivating the surface of the first electroactive material layer with air or another oxygen-containing gas such that the first interlayer material is an oxide of the first electroactive material.

49. A process according to any of statements 31 to 47, wherein step (c) comprises passivating the surface of the first electroactive material layer with (i) ammonia; (ii) a gas comprising ammonia and oxygen; or (iii) phosphine, such that the first interlayer material comprises a nitride, oxynitride or phosphide of the first electroactive material.

50. A process according to any of statements 31 to 47, wherein step (c) comprises passivating the surface of the first electroactive material layer with a passivating agent selected from one or more compounds of the formula:

R¹—CH═CH—R¹; (i)

R¹—C≡C—R¹; (ii)

O=CR¹R¹; (iii)

HX—R², and (iv)

HX—C(O)—R¹, (v)
wherein X represents O, S, NR¹ or PR¹; and
wherein each R¹ independently represents H or an unsubstituted or substituted aliphatic or aromatic hydrocarbyl group having from 1 to 20 carbon atoms, or wherein two R¹ groups form an unsubstituted or substituted ring structure comprising from 3 to 8 carbon atoms in the ring;
wherein R² represents an unsubstituted or substituted aliphatic or aromatic hydrocarbyl group having from 1 to 20 carbon atoms, or wherein R¹ and R² together form an unsubstituted or substituted ring structure comprising from 3 to 8 carbon atoms in the ring,
such that the first interlayer material comprises a carbon-containing organic moiety covalently bonded to the surface of the first electroactive material layer.

51. A process according to any of statements 31 to 50, wherein step (c) comprises depositing a layer of a conductive pyrolytic carbon material onto the, optionally passivated, surface of the first electroactive material layer.

52. A process according to any of statements 31 to 50, wherein step (c) comprises depositing a layer of a conductive metal onto the, optionally passivated, surface of the first electroactive material layer, optionally wherein the conductive metal is silver.

53. A process according to any of statements 31 to 50, wherein step (c) comprises depositing a layer of a lithium-ion permeable solid electrolyte onto the, optionally passivated, surface of the first electroactive material layer.

54. A process according to any of statements 31 to 53, wherein steps (c) and (d) are repeated one or more times to form a particulate material, comprising n electroactive material layers and (n−1) interlayer materials disposed between each of the electroactive material layers, wherein n is an integer from 3 to 20, or from 3 to 15, or from 3 to 12, or from 3 to 10, or from 4 to 10, or from 5 to 8.

55. A process according to statement 54, wherein each repetition of step (d) is independently as defined in any of statements 42 to 47, optionally wherein each of the n electroactive materials is the same electroactive material, optionally wherein each of the n electroactive materials is silicon.

56. A process according to statement 54 or statement 55, wherein each repetition of step (c) is independently as defined in any of statements 48 to 53, optionally wherein each of the (n−1) interlayer materials is the same interlayer material.

57. A process according to any of statements 31 to 56, further comprising the step of:
(e) forming a coating layer on the surface of the final electroactive material layer to be deposited,
   optionally wherein step (e) has any of the features of step (c) as defined in statements 48 to 53.

58. A composition comprising a particulate material as defined in any of statements 1 to 30 and at least one other component.

59. A composition according to statement 58, comprising from 1 to 95 wt %, or from 2 to 90 wt %, or from 5 to 85 wt %, or from 10 to 80 wt % of the particulate material as defined in statements 1 to 27, based on the total dry weight of the composition.

60. A composition according to statement 58 or statement 59, wherein the at least one other component is selected from: (i) a binder; (ii) a conductive additive; and (iii) an additional particulate electroactive material.

61. A composition according to statement 60, comprising at least one additional particulate electroactive material, optionally wherein the at least one additional particulate electroactive material is selected from graphite, hard carbon, silicon, tin, germanium, aluminium and lead.

62. An electrode comprising a particulate material as defined in any of statements 1 to 30 in electrical contact with a current collector, optionally wherein the particulate material is in the form of a composition as defined in any of statements 58 to 61.

63. A rechargeable metal-ion battery comprising:
(i) an anode, wherein the anode comprises an electrode as described in statement 62;
(ii) a cathode comprising a cathode active material capable of releasing and reabsorbing metal ions; and
(iii) an electrolyte between the anode and the cathode.

64. Use of a particulate material as defined in any of statements 1 to 30 as an anode active material.

65. Use according to statement 64, wherein the particulate material is in the form of a composition as defined in any of statements 58 to 61.

### EXAMPLE

### Preparation of Composite Particles in a Fluidized Bed Reactor

70 g of a particulate porous carbon framework was placed in a stainless steel fluidized bed reactor with a gas inlet consisting of 5 nozzles with 8×0.8 mm holes each, allowing for a disperse gas mixing. The cross sectional area of the fluidised bed is 0.058 m allowing for calculations of superficial velocities. The reactor was suspended from a frame and a vertically-oriented tube furnace was positioned such that the hot zone ran from the conical section to ¾ of the length of the cylindrical section (approx. 380 mm long). The minimum fluidization velocity was determined with a cold-flow pressure-drop test with nitrogen as an inert gas, ramping gas flow rate between 1 to 5 L/min. Once minimum fluidizing velocity was determined, the inert gas flow rate was held constant at or above the minimum fluidizing velocity. The furnace was ramped to the desired reaction temperature under constant inert gas flow rate. After stabilizing at a target temperature between 435-500° C., the fluidizing gas was switched from pure nitrogen to 4 vol % monosilane in nitrogen. The reaction progress was monitored by measuring pressure drop and furnace temperature difference between top and bottom. The gas flow rate was adjusted throughout the run to maintain a pressure drop consistent with continued fluidization and minimum temperature difference between the top and bottom of the bed of less than 100° C. was maintained. Dosing of monosilane is performed over a period of 6 hours or depending on the layer thickness, the reactor is then purged with nitrogen for 30 minutes to remove any excess monosilane. Then a pyrolytic carbon interlayer is formed by flowing through 30% Ethylene/Nitrogen mix for 30 minutes at temperatures between 300° C. — 500° C., then the reactor is purged with nitrogen for 30 minutes to remove any ethylene. The process of introducing monosilane and ethylene reactants was repeated depending on how many layers were needed. At the end of the layering technique the fluidizing gas was then switched to pure nitrogen whilst maintaining fluidisation, this purge lasted 30 minutes. Then the furnace was allowed to settle to ambient temperature over several hours. On reaching ambient temperature, the furnace atmosphere was switched to air gradually over a period of hours.

1-36. (canceled)

37. A particulate material in the form of a plurality of composite particles, wherein the composite particles comprise:
(a) a porous particle framework, wherein the total pore volume of pores having pore diameter in the range from 3.5 to 100 nm is P¹ cm³ per gram of the porous particle framework, as determined by nitrogen gas adsorption, where P¹ represents a number in the range from 0.3 to 2.4;
(b) a multilayer coating disposed on the internal pore surfaces of the porous particle framework, wherein the multilayer coating comprises at least:
(i) a first electroactive material layer;
(ii) a second electroactive material layer; and
(iii) a first interlayer material disposed between the first and second electroactive material layers.

38. The particulate material according to claim 37, wherein the porous particle framework is a conductive porous particle framework.

39. The particulate material according to claim 38, wherein the conductive porous particle framework is a conductive porous carbon particle framework, optionally wherein the conductive porous carbon particle framework comprises at least 80 wt % carbon.

40. The particulate material according to claim 37, wherein P¹ is in the range from 0.8 to 2.3.

41. The particulate material according to claim 37, wherein the volume fraction of pores having a pore diameter in the range from 5 to 60 nm is at least 50 vol %, based on the total pore volume of pores having pore diameter in the range from 3.5 to 100 nm in the porous particle framework.

42. The particulate material according to claim 37, wherein the total volume of pores having diameter less than 3.5 nm in the porous particle framework, as determined by nitrogen gas adsorption, is P² cm³/g, wherein P² represents a number having a value of less than 0.25.

43. The particulate material according to claim 37, wherein the total volume of pores having diameter less than 3.5 nm in the porous particle framework, as determined by nitrogen gas adsorption, is P² cm³/g, wherein P² is no more than [0.5×P¹].

44. The particulate material according to claim 37, wherein the porous particle framework has a BET surface area in the range from 250 m²/g to 2,500 m²/g.

45. The particulate material according to claim 37, wherein the first and second electroactive material layers independently comprise an electroactive material selected from elemental silicon, elemental tin, elemental germanium, elemental aluminium, and mixtures and alloys thereof.

46. The particulate material according to claim 37, wherein the first and second electroactive material layers both comprise elemental silicon.

47. The particulate material according to claim 37, wherein the first interlayer material comprises a passivation layer formed on the surface of the first electroactive material layer, wherein the passivation layer is an oxide, nitride, oxynitride or carbide of the first electroactive material.

48. The particulate material according to claim 37, wherein the first interlayer material comprises a passivation layer formed on the surface of the first electroactive material layer, wherein the passivation layer comprises a carbon-containing organic moiety covalently bonded to the surface of the first electroactive material layer.

49. The particulate material according to claim 37, wherein the first interlayer material comprises a conductive pyrolytic carbon material, a conductive metal layer, or a lithium-ion permeable solid electrolyte.

50. The particulate material according to claim 37, wherein the multilayer coating comprises n electroactive material layers and (n−1) interlayer materials disposed between each of the electroactive material layers, wherein n is an integer from 3 to 20.

51. The particulate material according to claim 50, wherein:
(i) each of then electroactive materials is silicon; and
(ii) each of the (n−1) interlayer materials is independently a passivation layer formed on the surface of the first electroactive material layer, wherein the passivation layer is an oxide, nitride, oxynitride or carbide of the first electroactive material or a carbon-containing organic moiety covalently bonded to the surface of the first electroactive material layer; or comprises a conductive pyrolytic carbon material, a conductive metal layer, or a lithium-ion permeable solid electrolyte.

52. The particulate material according to claim 37, wherein further comprising:
(iv) a coating layer disposed on the surface of the outermost electroactive material layer.

53. The particulate material according to claim 37, wherein the amount of electroactive material in the composite particles of the invention is selected such that at least 25% and up to 80% of the internal pore volume of the porous particle framework is occupied by the electroactive material(s) and interlayer material(s).

54. The particulate material according to claim 37, wherein the composite particles comprise from 35 wt % to 75 wt % silicon.

55. The particulate material according to claim 37, wherein at least 85 wt %, more preferably at least 90 wt %, more preferably at least 95 wt %, more preferably at least 98 wt % of the electroactive material mass in the composite particles is located within the internal pore volume of the porous particle framework.

56. The particulate material according to claim 37, wherein the composite particles have a D₅₀ particle diameter in the range from 0.5 to 200 μm.

57. A process for preparing composite particles, comprising:
(a) providing a plurality of porous particles, wherein the total pore volume of pores having pore diameter in the range from 3.5 to 100 nm is P¹ cm³ per gram of the porous particles, as determined by nitrogen gas adsorption, where P¹ represents a number in the range from 0.3 to 2.4;
(b) depositing a first electroactive material layer onto the internal pore surfaces of the porous particles;
(c) forming a first interlayer material on the surface of the first electroactive material layer;
(d) depositing a second electroactive material layer onto the surface of the first interlayer material.

58. A composition comprising a particulate material as defined in claim 37 and at least one other component.

59. An electrode comprising a particulate material as defined in claim 37 in electrical contact with a current collector.

60. A rechargeable metal-ion battery comprising:
(i) an anode, wherein the anode comprises an electrode as described in claim 59
(ii) a cathode comprising a cathode active material capable of releasing and reabsorbing metal ions; and
(iii) an electrolyte between the anode and the cathode.
